(19) United States
(12) Patent Application Publication
(10) Pub. No.: US 2024/0094111 A1
(43) Pub. Date: Mar. 21, 2024

(54) METHOD AND DEVICE FOR NONDESTRUCTIVELY AND IN-SITU MONITORING CORROSION IN OBJECT

(71) Applicants: AUBURN UNIVERSITY, Auburn, AL (US); NASA/MARSHALL SPACE FLIGHT CENTER, MSFC, AL (US)

(72) Inventors: Zhongyang Cheng, Auburn, AL (US); Terry Dewayne Rolin, MFSC, AL (US); Yaqub Adediji, Auburn, AL (US); Jindong Wei, Auburn, AL (US)

(21) Appl. No.: 18/370,138

(22) Filed: Sep. 19, 2023

Related U.S. Application Data
(60) Provisional application No. 63/376,175, filed on Sep. 19, 2022.
(60) Provisional application No. 63/533,403, filed on Aug. 18, 2023.

(51) Int. Cl. G01N 17/02

(52) U.S. Cl. CPC G01N 17/02

(57) ABSTRACT

The invention in one aspect relates to a method for nondestructively detecting corrosion of an object such as metallic cables. The method includes applying an electronic signal to a device under test (DUT) including said object; measuring signal-transmission characteristics of said object; and determining the corrosion of the object based on the measured signal-transmission characteristics of said object.

### CROSS-REFERENCE TO RELATED PATENT APPLICATIONS

This application claims priority to and the benefit of U.S. Provisional Patent application Serial Nos. 63/376,175, filed Sep. 19, 2022, and 63/533,403, filed Aug. 18, 2023, which are incorporated herein in their entireties by reference.

### STATEMENT AS TO RIGHTS UNDER FEDERALLY-SPONSORED RESEARCH

This invention was made with United States Government support under grant number 80NSSC21M0288 awarded by the National Aeronautics and Space Administration. The Government has certain rights in the invention.

### FIELD OF THE INVENTION

The present invention relates to method and device for nondestructively and in-situ monitoring corrosion in an object such as cables and/or wires.

### BACKGROUND OF THE INVENTION

The background description provided herein is for the purpose of generally presenting the context of the present invention. The subject matter discussed in the background of the invention section should not be assumed to be prior art merely as a result of its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the present invention.

Corrosion occurs when a chemical reaction takes place in an environment that surrounds a material (e.g., cables, wires) which initiates/causes a slow deterioration and weakening of the material over time. Water, H₂, O₂, an electric current, dirt, or bacteria located in the environment that comes in contact with a material, such as metal in a cable, undergoes an electrochemical reaction resulting in corrosion. The type of metal used in wire/cable construction (e.g., copper), the type of insulating material, and the amount/duration of exposure to H₂O or O₂, or other material will ultimately determine the rate and form of corrosion (e.g., pitting, generalized/uniform, crevice, intergranular, stress corrosion cracking, galvanic). In 2013, the National Association of Corrosion Engineers (NACE) estimated that on a global basis, the detrimental effects of corrosion of all types cost the industry/consumers $2.5 trillion.

Corrosion, either internal to a wire or on its surface in electrical components, wiring systems, electronics, and wire harnesses (e.g., flight harnesses), can affect the product's ability to function properly/transmit an electric signal. Specific to flight harnesses (e.g., NASA, space-grade), red plague (cuprous oxide corrosion) can develop in silver-coated soft or annealed copper conductors (component leads, single and multi-stranded wires, printed circuit board (PCB) conductors) when a galvanic cell forms between the copper base metal and the silver coating in the presence of H₂O and O₂. As a result, the silver plating is damaged, exposing the copper wire to H₂O or high temperatures, making it susceptible to corrosion. The copper wire begins to corrode, resulting in irreversible destruction, with the copper eventually dissolving completely, leaving behind the damaged silver-plating shell. The sliver plating alone cannot perform without the copper wire interior, thus rendering the wire nonfunctional. NASA has developed red plague control plans (RPCP) to prevent/mitigate the harmful effects of this type of corrosion on flight harnesses which focus on a variety of issues, assuring that the strand materials and coatings are manufactured in accordance with recognized ASTM or ANSI standards, use of qualified/approved suppliers/OEM, not using/storing procured wires/cables that are greater than 10 years old, protecting silver-coated wire/cables from environmental conditions which can cause red plague, proper shipping/packaging techniques, and use of stringent assembly/quality control techniques.

To assess the health of flight/wire harnesses, typical tests include a range of pre-operative/manufacturing techniques such as build tests (e.g., cable/wire length, routing ability), electrical measurements (e.g., insulation, dielectric, and/or contact resistance), mechanical assessments (stress, immersion), product durability (connector mating/de-mating) evaluations, and environmental (e.g., thermal, moisture resistance, vibration, O₃ exposure, mildew resistance) tests. Corrosion testing of such harness systems was also identified for use in a pre-operative mode; AS4373 Method 60811 to quantify fluoride evolution to assess the likelihood of red plague, AS4373 Method 610, AS4373 Method 611, and AS4373 Method 61212. From an as-built perspective, standard corrosion tests of the destructive variety were identified, which primarily include optical microscopy techniques and scanning electron microscope SEM) to gauge wire corrosion which is performed under laboratory conditions. No technique was identified allowing for corrosion identification of wires/cables in a harness in an in-situ mode.

Therefore, a heretofore unaddressed need exists in the art to address the aforementioned deficiencies and inadequacies.

### SUMMARY OF THE INVENTION

In view of the foregoing, this invention discloses a method and a device for nondestructively and in-situ monitoring corrosion in an object.

In one aspect of the invention, the method for nondestructively detecting corrosion of an object comprising applying an electronic signal to a device under test (DUT) containing said object; measuring signal-transmission characteristics of said object; and determining the corrosion of the object based on the measured signal-transmission characteristics of said object.

In one embodiment, said object includes a metallic cable or wire.

In one embodiment, the electronic signal varies in frequency in a range of 9 kHz-3 GHz.

In one embodiment, the signal-transmission characteristics comprises one or more of S-parameter signals at different frequencies, wherein the S-parameter signals include an input impedance, S₁₁, an output match/impedance, S₁₂, a forward gain/loss, S₂₁, and a reverse gain/loss, S₂₂, of the object.

In one embodiment, a magnitude of interference in the S-parameter signals is proportional to an amount, area, and depth of corrosion spots on said object.

In one embodiment, the S-parameter signals at a frequency range of 10 MHz-1 GHZ are sensitive to the corrosion.

In one embodiment, the frequency range is preferably from 10 MHz to 100 MHz.

In one embodiment, said determining the corrosion of said object comprises comparing the measured signal-transmission characteristics of said object with that of a known object in an uncorroded state to determine difference of the signal-transmission characteristics between said object and the known object.

In one embodiment, the known object is corresponding to said object in an uncorroded state.

In one embodiment, the signal-transmission characteristics of the known object is measured in-situ, or pre-measured.

In one embodiment, said determining the corrosion of said object comprises characterizing a roughness in the S-parameter signals; and determining the corrosion of said object based on the roughness in the S-parameter signals.

In one embodiment, the roughness in the S-parameter signals increases as the corrosion time point increases.

In an aspect of the invention, the device for nondestructively detecting corrosion of an object, comprising a signal source for generating an electronic signal operably applied to a device under test (DUT) containing said object; a detector configured to measure signal-transmission characteristics of said object; and a processor configured to determine the corrosion of the object based on the measured signal-transmission characteristics of said object.

In one embodiment, said object includes a metallic cable or wire.

In one embodiment, the electronic signal varies in frequency in a range of 9 kHz-3 GHz.

In one embodiment, the signal-transmission characteristics comprises one or more of S-parameter signals at different frequencies.

In one embodiment, the S-parameter signals include an input impedance, S₁₁, an output match/impedance, S₁₂, a forward gain/loss, S₂₁, and a reverse gain/loss, S₂₂, of the object.

In one embodiment, a magnitude of interference in the S-parameter signals is proportional to an amount, area, and depth of corrosion spots on the object.

In one embodiment, the S-parameter signals at a frequency range of 10 MHz-1 GHZ are sensitive to the corrosion.

In one embodiment, the frequency range is preferably from 10 MHz to 100 MHz.

In one embodiment, the processor is configured to compare the measured signal-transmission characteristics of said object with that of a known object to determine difference of the signal-transmission characteristics between said object and the known object so as to determine the corrosion of said object.

In one embodiment, the known object is corresponding to said object in an uncorroded state.

In one embodiment, the signal-transmission characteristics of the known object is measured in-situ, or pre-measured.

In one embodiment, the processor is configured to characterize a roughness in the S-parameter signals; and determine the corrosion of said object based on the roughness in the S-parameter signals.

In one embodiment, the roughness in the S-parameter signals increases as the corrosion time point increases.

In one embodiment, the signal source comprises a signal generator.

In one embodiment, the detector comprises one or more receivers connected to its ports of the DUT.

In one embodiment, the device is a network analyzer.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the present invention and, together with the written description, serve to explain the principles of the invention.

Wherever possible, the same reference numbers are used throughout the drawings to refer to the same or like elements of an embodiment.

FIG. 1A shows schematically the device for nondestructively detecting corrosion of an object such as metallic cables according to embodiments of the invention.

FIG. 1B shows schematically S-parameter readings/signals of a device under test (DUT).

FIG. 2 shows schematically an experiment setup for nondestructively detecting corrosion of an object according to embodiments of the invention.

FIG. 3 shows S-parameter results for cables in dry and wet solder conditions at Day 0 at the frequency range of 9 kHz-3 GHz FIG. 4 shows 15-months S-parameter results for cables in dry conditions at the frequency range of 9 kHz-10 MHz.

FIG. 5 shows 15-months S-parameter results for cables in dry solder conditions at the frequency range of 10 MHz-100 MHz.

FIG. 6 shows 12-months S-parameter results for cables in dry conditions at the frequency range of 100 MHz-600 MHz.

FIG. 7 shows 12-months S-parameter results for cables in dry and wet solder conditions at the frequency range of 600 MHz-3 GHz.

FIG. 8 shows numerical difference between transmission parameters (S₁₂, S₂₁) of cables in wet condition (real) at the frequency range of 10 MHz-100 MHz.

FIG. 9 shows numerical difference between transmission parameters (S₁₂, S₂₁) of cables in wet and dry conditions at the frequency range of 10 MHz-100 MHz.

FIG. 10 shows schematic of skin effect of a cable.

FIG. 11 shows frequency ranges used for nondestructively detecting corrosion of an object such as metallic cables.

FIG. 12 shows schematically an experiment setup for nondestructively detecting corrosion of an object according to embodiments of the invention.

FIG. 13. shows S-parameter results for cables in dry and wet solder conditions at Day 1 at the frequency range of 9 kHz-3 GHz.

FIG. 14 shows 5-months S-parameter results for cables in dry and wet conditions at the frequency range of 9 kHz-10 MHz.

FIG. 15 shows 5-months S-parameter results for cables in dry conditions at the frequency range of 10 MHz-100 MHz.

FIG. 16 shows. 12-months S-parameter results for cables in dry conditions at the frequency range of 100 MHz-600 MHz.

FIG. 17 shows 12-months S-parameter results for cables in dry conditions at the frequency range of 600 MHz-3 GHz.

FIG. 18 shows numerical difference between transmission parameters (S₁₂, S₂₁ magnitude) of cable in a wet condition at the frequency range of 10 MHz-100 MHz.

FIG. 19 shows numerical difference between transmission parameters (S₁₂, S₂₁) of cables in wet and dry conditions at the frequency range of 10 MHz-100 MHz.

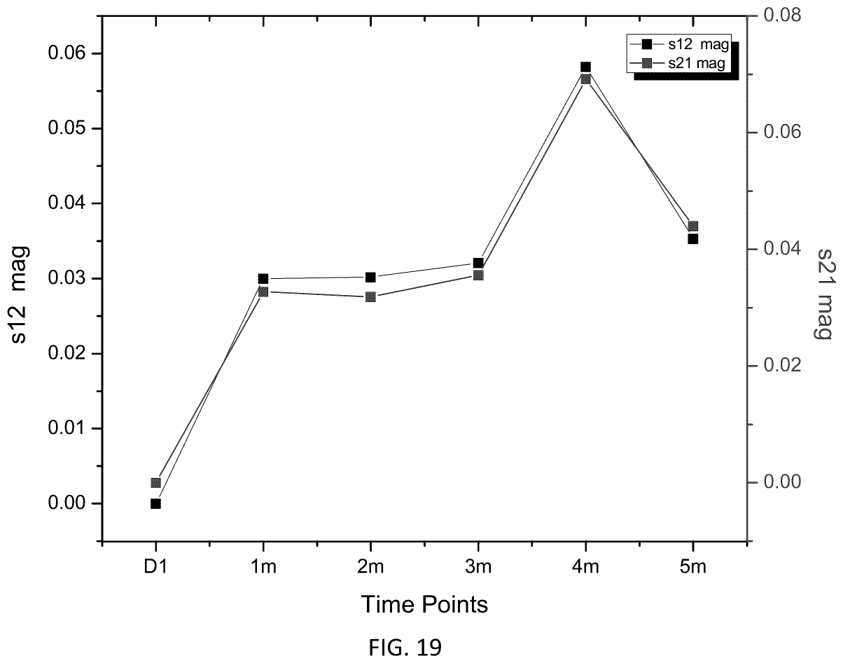

FIG. 20 shows schematically an experiment setup for nondestructively detecting corrosion of an object according to embodiments of the invention.

FIG. 21 shows 5-months S-parameter results for cables in dry and wet solder conditions at the frequency range of 10 MHz-100 MHz.

FIG. 22 shows 12-months S-parameter results for cables in dry and wet solder conditions at the frequency range of 100 MHz-600 MHz.

FIG. 23 shows numerical difference between transmission parameters (S₁₂, S₂₁ magnitude) of cables in wet condition at the frequency range of 10 MHz-100 MHz.

FIG. 24A shows computing difference between S-signals (S₁₁, S₁₂, S₂₁, S₂₂) of cables in dry conditions and fresh cable at different corrosion time points at the frequency range of 10 MHz-100 MHz.

FIG. 24B shows computing difference between S-signals (S₁₁, S₁₂, S₂₁, S₂₂) of cables in dry conditions and fresh cable at different corrosion time points at the frequency range of 100 MHz-600 MHz.

FIG. 25A shows computing difference between S-signals (S₁₁, S₁₂, S₂₁, S₂₂) of cables in wet conditions and fresh cable at different corrosion time points at the frequency range of 10 MHz-100 MHz.

FIG. 25B shows computing difference between S-signals (S₁₁, S₁₂, S₂₁, S₂₂) of cables in wet conditions and fresh cable at different corrosion time points from 100 MHz-600 MHz.

FIG. 26A shows computing difference between S-signals (S₁₁, S₁₂, S₂₁, S₂₂) of cables in wet and dry condition at different corrosion time points at the frequency range of 10 MHz-100 MHz.

FIG. 26B shows computing difference between S-signals (S₁₁, S₁₂, S₂₁, S₂₂) of cables in wet and dry condition at different corrosion time points at the frequency range of 100 MHz-600 MHz.

FIG. 27 shows computing difference between S-signals (S₁₁, S₁₂, S₂₁, S₂₂) of cables in dry conditions and fresh cable at different corrosion time points at the frequency range of 10 MHz-100 MHz and 100 MHz-600 MHz.

FIG. 28 shows computing difference between S-signals (S₁₁, S₁₂, S₂₁, S₂₂) of cables in wet conditions and fresh cable at different corrosion time points at the frequency range of 10 MHz-100 MHz and 100 MHz-600 MHz.

FIG. 29 shows computing difference between S-signals (S₁₁, S₁₂, S₂₁, S₂₂) of cables and fresh cable at different corrosion time points at the frequency range of 10 MHz-100 MHz.

FIG. 30 shows computing difference between S-signals (S₁₁, S₁₂, S₂₁, S₂₂) of cables and fresh cable at different corrosion time points at the frequency range of 100 MHz-600 MHz.

### DETAILED DESCRIPTION OF THE INVENTION

The present invention will now be described more fully hereinafter with reference to the accompanying drawings, in which exemplary embodiments of the present invention are shown.

The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting and/or capital letters has no influence on the scope and meaning of a term; the scope and meaning of a term are the same, in the same context, whether or not it is highlighted and/or in capital letters. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only and in no way limits the scope and meaning of the invention or of any exemplified term. Likewise, the invention is not limited to various embodiments given in this specification.

The terminology used herein is for the purpose of describing particular embodiments only and is not intended to be limiting of the invention. As used herein, the singular forms “a,” “an,” and “the” are intended to include the plural forms as well, unless the context clearly indicates otherwise.

It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will also be appreciated by those of skill in the art that references to a structure or feature that is disposed “adjacent” to another feature may have portions that overlap or underlie the adjacent feature.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below can be termed a second element, component, region, layer or section without departing from the teachings of the present invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation shown in the figures. For example, if the device in one of the figures is turned over, elements described as being on the “lower” side of other elements would then be oriented on the “upper” sides of the other elements. The exemplary term “lower” can, therefore, encompass both an orientation of lower and upper, depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be further understood that the terms “comprise(s)” and/or “comprising,” or “include(s)” and/or “including” or “has (have)” and/or “having” or “contain(s)” and/or “containing” when used in this specification specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around,” “about,” “substantially” or “approximately” shall generally mean within 20 percent, preferably within 10 percent, and more preferably within 5 percent of a given value or range. Numerical quantities given herein are approximate, meaning that the terms “around,” “about,” “substantially” or “approximately” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in different order (or concurrently) without altering the principles of the invention.

Corrosion is a critical issue for all metallic compounds. Cables and wires, which are made of metallic compounds, are widely used in all electronic and electric systems. When it is expose to the environment with oxygen and water molecules, the corrosion will occur at the surface first and then, grows in both directions, i.e., in-plane and out-plane direction, the latter is the depth of the corrosion. The corrosion appeared on/in a cable will affect its capability on transforming electric signal and power. For example, for electronic signal transformation, the corrosion in/on a cable would affect the integrity of signal transforming through cable. For electrical power supplier, the corrosion will affect the capacity of a cable for transforming power; during the power transformation, extra-heat can be generated locally around the corrosion area, which will further accelerate the corrosion. When the corrosion is grown to a certain level, the cable would lose its capability to transform power, which would cause a disaster for the system that relies on the power transformed through the cable.

The corrosion on a material is strongly affected by many factors, such as temperature and humidity of the environment, the exact composition of the material, and the things around the material. Therefore, it is challenged to predicate the stage of corrosion on a cable in a system. For the safety of system operation, it is important to know the stage of corrosion for the cables used in the system. Although it is very simple and easy to observe the corrosion by using optic microscopy, this technique requires wires of interest to be removed from the cable harness and then destructively removing the insulating jacket for the observation. There are many destructive methods that have been well developed and widely used to determine the seriousness of corrosion in a material including on a cable. However, no methodology for nondestructively and in-situ monitoring corrosion in cables and/or wires is reported.

In view of the aforementioned deficiencies and inadequacies, aspects of this invention provide a nondestructive technology utilized to evaluate the seriousness of corrosion on/in a metallic object such as a cable or wire. The nondestructive technology is based on the characteristics of a metallic object on transforming an electric signal at different frequencies.

Due to skin effect, the electric field of the electronic signal carried by an object such as a cable is concentrated in the layer near its surface. The higher the frequency of the electronic signal, the stronger the skin effect. Therefore, the impact of the corrosion in/on a cable on its signal transformation characteristics is strongly dependent on the frequency of the electronic signal. The higher the frequency, the stronger the impact, due to the fact that the corrosion is started on the outside surface of the cable. However, if the frequency is too high, there are too many factors that would affect the signal transformation characteristics of a cable. For example, the surface smoothness and cross-section uniformity of a cable and other materials that is close to the cable would affect the signal transformation characteristics at high frequencies. At lower frequencies, since the skin effect is weak, the impact/influence of the corrosion on signal transformation characteristics can be estimated by the percentage of corrosion over the cross-section of the cable that usually is small. The methodology uses vector analyses, differentiation, and certain frequency ranges that have heretofore never been used and therefore are novel and unique.

Accordingly, this invention is based on the usage of signal transformation characteristics of a cable at the middle frequencies that is sensitive enough to identify the seriousness of the corrosion and, at the same time, is not affected by many other factors such as humidity and temperature.

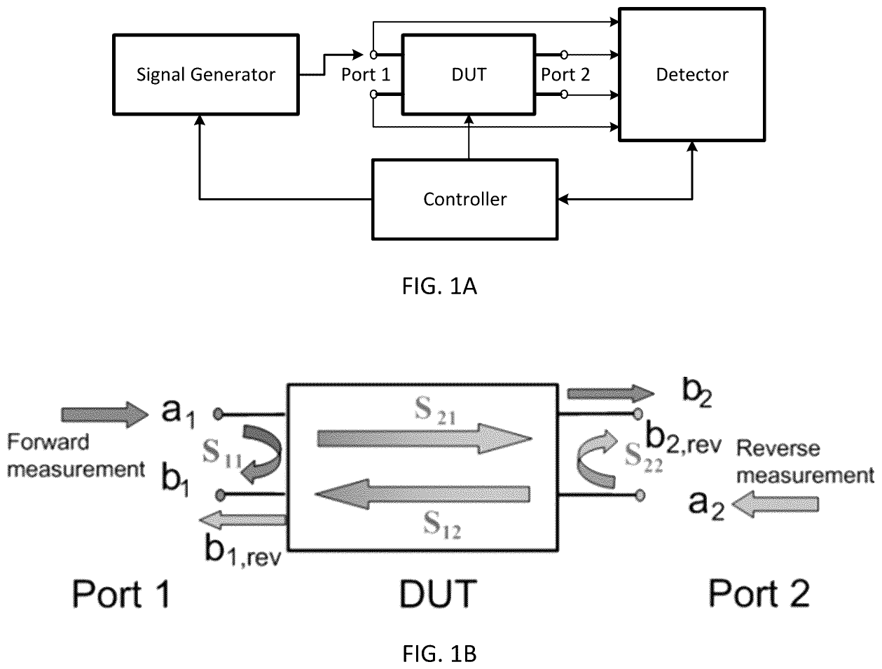

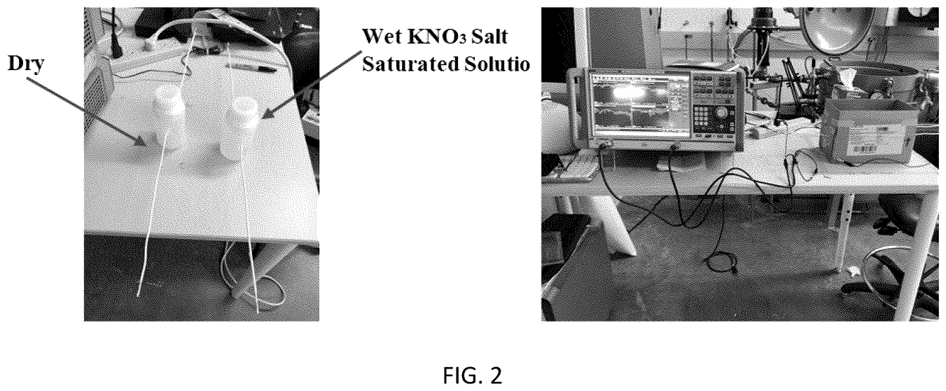

A cable can be simulated/treated as an electronic device. When an electronic signal is applied on a cable, partial of the signal is transmitted and partial is reflected as shown in FIGS. 1A-1B. This behavior can be characterized using a network analyzer, such as a vector network analyzer (VNA), which is a measurement instrument used to characterize/measure various passive devices (e.g., cables, wires, filters, attenuators) in an electrical network, including S-parameters. The VNA measures the frequency response of an individual component, or a network composed of multiple components. VNAs measure the power of a high-speed signal going into and coming back from a component or a network, with both amplitude and phase of the high-frequency signal captured at each frequency point, with the computer in the VNA calculating key parameters (e.g., return loss, insertion loss) of the network under test. In high-speed system tests, the VNA can be used to characterize multi-port networks consisting of various components (e.g., connectors, filters, amplifiers, transmission line/coaxial channels).

In some embodiments of the invention, the VNA is used to measure the S-parameters including S₁₁, S₁₂, S₂₂, and S₂₁ as shown in FIG. 1B, where S₁₁ measures the input impedance, S₁₂ measures the output match/impedance, S₂₁ measures the forward gain/loss, and S₂₂ measures the reverse gain/loss, of the device/cable, respectively. Using the network analyzer, all the S-parameters can be determined at different frequencies.

According to the invention, a prototype, non-destructive technology to detect and measure corrosion either on or in a cable by application of an electric signal using a range of frequencies has been developed. The technique uses a commercially available VNA and the signal transformation characteristics of a cable using mid-range frequencies (e.g., 100 MHz-1 GHz). The technique is performed under dry conditions and under RH levels <90% (e.g., wet) with a primary application for assessment of corrosion in wire harnesses. S-parameters are characterized/measured by the VNA in a cable after application of the electronic signal at the different frequencies. The difference in the various S-parameters between the two cables, dry and wet, as measured by the VNA, is used to assess the extent of cable/wire corrosion.

In some examples, an evaluation of two cables was conducted whereby the four S-parameters (S₁₁, S₁₂, S₂₁, S₂₂) were characterized by the VNA over time (e.g., 0-15 months) for each cable. The difference in the four S-parameter values was calculated/plotted across a frequency range of 100 MHz-600 MHz. An assessment of these differences indicated that as time increases, the differences between the S-permeants all increase, with elevated levels of corrosion identified in the wet cable as compared to the dry cable. Differences were more pronounced at times between 4-5 months. The use of signal frequencies across the middle range; 100 MHz-1 GHz, was shown to be more sensitive to cable corrosion than lower frequencies; <100 MHz, or high frequencies; >1 GHz.

As discussed in the following example section, the data/results clearly demonstrate that the difference in the S-parameters between two cables increases with the frequency. That is, the S-parameters can be used to evaluate the seriousness of corrosion on a cable.

To further quantify difference, the difference in the S-parameters between two cables is defined as

Difference=∫_{f}_{₁}^{f}^{₂}[S1(f)−S2(f)]²df

where f₁ and f₂ are the starting and ending frequencies, respectively, while S1(f) and S2(f) are the S-parameters of cable-1 and cable-2 at frequency f. The difference definition here was calculated for all four S-parameters using the results obtained at different times, where one cable was kept in a dry environment and the other is in a high humidity environment (90% R.H.).

Using the definition of “difference”, the difference between two cables at different time was calculated for all four S-parameters obtained at different times. Clearly, all these differences increase with time. That is, as time goes, the corrosion in/on the cable in the high humidity condition increases, while the corrosion in/on the cable in the dry condition would not change much. In other words, as time goes, the difference in corrosion between two cables increases with time.

To further illustrate the principles of the invention and their practical application, certain exemplary embodiments of the invention are described below.

In one exemplary embodiment, the method for nondestructively detecting corrosion of an object includes applying an electronic signal to a DUT containing said object; measuring signal-transmission characteristics of said object; and determining the corrosion of the object based on the measured signal-transmission characteristics of said object.

In one exemplary embodiment, said object includes a metallic cable or wire.

In one exemplary embodiment, the electronic signal varies in frequency in a range of 9 kHz-3 GHz.

In one exemplary embodiment, the signal-transmission characteristics comprises one or more of S-parameter signals at different frequencies. The S-parameter signals include an input impedance, S₁₁, an output match/impedance, S₁₂, a forward gain/loss, S₂₁, and a reverse gain/loss, S₂₂, of the object.

In one exemplary embodiment, a magnitude of interference in the S-parameter signals is proportional to an amount, area, and depth of corrosion spots on said object.

In one exemplary embodiment, the S-parameter signals at a frequency range of 10 MHz-1 GHZ are sensitive to the corrosion.

In one exemplary embodiment, the frequency range is preferably from 10 MHz to 100 MHz.

In one exemplary embodiment, said determining the corrosion of said object comprises comparing the measured signal-transmission characteristics of said object with that of a known object in an uncorroded state to determine difference of the signal-transmission characteristics between said object and the known object.

In one exemplary embodiment, the known object is corresponding to said object in an uncorroded state.

In one exemplary embodiment, the signal-transmission characteristics of the known object is measured in-situ, or pre-measured.

In one exemplary embodiment, said determining the corrosion of said object comprises characterizing a roughness in the S-parameter signals; and determining the corrosion of said object based on the roughness in the S-parameter signals.

In one exemplary embodiment, the roughness in the S-parameter signals increases as the corrosion time point increases.

In one exemplary embodiment, as shown in FIG. 1A-1B, the device for nondestructively detecting corrosion of an object includes a signal source, e.g., signal generator, for generating an electronic signal operably applied to the DUT containing said object; a detector coupled with the DUT and configured to measure signal-transmission characteristics of said object; and a controller, e.g., processor(s), coupled with the detector and configured to determine the corrosion of the object based on the measured signal-transmission characteristics of said object. In addition, the controller may also be coupled to the DUT and/or the signal generator for controlling operations thereof.

In one exemplary embodiment, the processor is configured to compare the measured signal-transmission characteristics of said object with that of a known object to determine difference of the signal-transmission characteristics between said object and the known object so as to determine the corrosion of said object.

In one exemplary embodiment, the detector comprises one or more receivers connected to its ports of the DUT.

In one exemplary embodiment, said object includes a metallic cable or wire.

In one exemplary embodiment, the electronic signal varies in frequency in a range of 9 kHz-3 GHz.

In one exemplary embodiment, the signal-transmission characteristics comprises one or more of S-parameter signals at different frequencies.

In one exemplary embodiment, the S-parameter signals include an input impedance, S₁₁, an output match/impedance, S₁₂, a forward gain/loss, S₂₁, and a reverse gain/loss, S₂₂, of the object.

In one exemplary embodiment, a magnitude of interference in the S-parameter signals is proportional to an amount, area, and depth of corrosion spots on the object.

In one exemplary embodiment, the S-parameter signals at a frequency range of 10 MHz-1 GHZ are sensitive to the corrosion.

In one exemplary embodiment, the frequency range is preferably from 10 MHz to 100 MHz.

In one exemplary embodiment, the known object is corresponding to said object in an uncorroded state.

In one exemplary embodiment, the signal-transmission characteristics of the known object is measured in-situ, or pre-measured.

If the signal-transmission characteristics of the known object is pre-measured, it may be stored in cloud server(s) and/or database(s). When the controller (processor) compares the measured signal-transmission characteristics of said object with the pre-measured signal-transmission characteristics of the known object, it may directly communicate with the cloud server(s) and/or the database(s), to determine difference of the signal-transmission characteristics between said object and the known object so as to determine the corrosion of said object.

In one exemplary embodiment, the processor is configured to characterize a roughness in the S-parameter signals; and determine the corrosion of said object based on the roughness in the S-parameter signals.

In one exemplary embodiment, the roughness in the S-parameter signals increases as the corrosion time point increases.

In one exemplary embodiment, the device is a network analyzer, such as a VNA.

The invention provides among other things, the following advantages.

As developed, the technology can be applied to identify corrosion in already constructed flight harnesses, thereby mitigating the need to conduct destructive testing to assess wire/cable corrosion, thereby lowering testing costs.

The developed technique to detect/measure corrosion either on or in a cable by application of an electric signal over a range of frequencies can be performed using commercially available components (e.g., VNA), contributing to system scalability in commercial use.

The novel cable corrosion detection technique is non-destructive, alleviating the need to remove a given cable from a wire harness and destroy it (e.g., remove cable insulation) to perform a corrosion measurement.

Evaluation of mid-frequency signals (about 100 MHz-1 GHz) to characterize wire/cable corrosion appears to be an unexplored area.

Among other things, the invention can find applications in the fields of wire harness, cable corrosion, aerospace, space/defense, automotive, electricity/power generation markets, and the like.

These and other aspects of the present invention are further described below. Without intent to limit the scope of the invention, exemplary instruments, apparatus, methods and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example

### Nondestructive Technology for Red Plague Corrosion Detection and Monitoring

In order to develop a non-destructive technology for red plague corrosion monitoring, the time dependent S-parameter results were obtained from the cables using the vector network analyzer at different corrosion time points. S-parameters describe how the cables modify a signal transmitted or reflected in a forward or reverse direction. Four S-parameter Sᵢⱼ measurements —Sn (input impedance), S₁₂ (output match/impedance), S₂₁ (forward gain/loss), and S₂₂ (reverse gain/loss) are obtained by passing electromagnetic signals through the device under test (DUT) as depicted in the schematic in FIGS. 1A-1B.

In this example, the DUT is the silver-plated copper cables and interference is expected to be generated in output S-parameter signals (S₁₁, S₁₂, S₂₁, S₂₂) due to interactions of the waves/signals with dirty connections and corroded spots on the cables across different frequency ranges. The magnitude of interference in the S-parameter signals is expected to be proportional to the amount, area, and depth of corrosion spots on the cables. This proportional relationship implies that higher levels of interference would indicate greater corrosion, and vice versa. By analyzing these signals, we can discern information about the extent of corrosion on the cables, providing a non-destructive method of representing corrosion status in the cables. However, the primary challenge lies in the complexity involved in extracting precise corrosion data from the S-parameter signals as it requires sophisticated data analysis and interpretation techniques to distill meaningful information about the corrosion.

In order to develop the nondestructive technology for red plague corrosion detection and monitoring, three sets of experiments, namely first set, second set and third set, have been set up. The first set contains two 12-inches-long thick silver coated cables with soldered joints placed in a wet and dry condition at room temperature. The rate of corrosion of the cable in wet condition is expected to be higher than the dry condition due to increase in moisture content around the cable. The second set also contains two 12-inches-long thick silver coated cables with soldered joints placed in a wet and dry condition at room temperature to verify the results obtained in the first set of experiment. The third set of experiment contains a 12-inches-long silver-coated copper cable with insulation, a stripped 12-inches-long cable without insulation and 12-inches-long cable with solder joint, all maintained at 90° F. and 90% relative humidity to further verify the effect of corrosion on the S-parameter readings and confirm the results obtained in the first and second set of experiments.

The frequency ranges of the S-parameter signals were divided into four ranges, namely low frequency (9 kHz-10 MHz), medium frequencies; frequency range A (10 MHz-100 MHz) and frequency range B (100 MHz-600 MHz), and high frequency (600 MHz-3 GHz). For the sake of clarity, the S₂₁ S-parameter signal (magnitude) and frequency range B (100 MHz-600 MHz) are focused mainly on because it shows a clearer trend. It should be noted that other S-parameter signals and frequency ranges can also be utilized to practice the invention.

### First Set

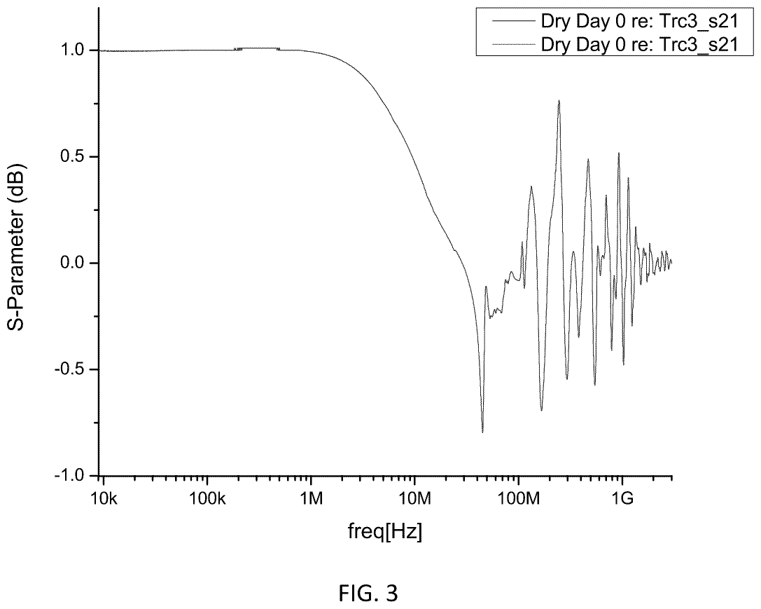

The first set contains two 12-inches-long thick silver coated cables with soldered joints placed in a wet and dry condition at room temperature as shown in FIG. 2.

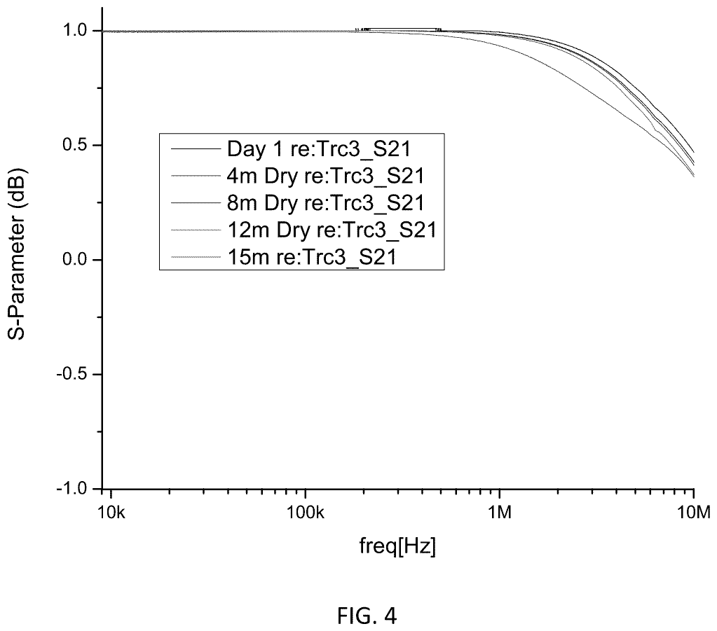

Firstly, the S-parameter readings were obtained for the cables with solder joints in wet and dry conditions at the beginning of the experiment (day 0). FIG. 3 shows the S-parameter reading (S₂₁) at the beginning of the experiment for the whole frequency spectrum (9 kHz to 3 GHz). As shown in FIG. 3, the S-parameter readings for the cables in wet and dry conditions are the same in all frequency ranges at the start of the experiment.

Low Frequency Range: As shown in FIG. 4, after the 15-months corrosion time point, the S-parameter readings (S₂₁) of the wet and dry solder joints showed no significant difference in the low frequency range (9 kHz to 10 MHz), especially below 1 MHz. This shows that corrosion does not affect the S-parameter readings of the cables in this range. Therefore, the rate of corrosion of the cables in wet and dry conditions has no influence on the S-parameter readings of the cables in the low frequency range.

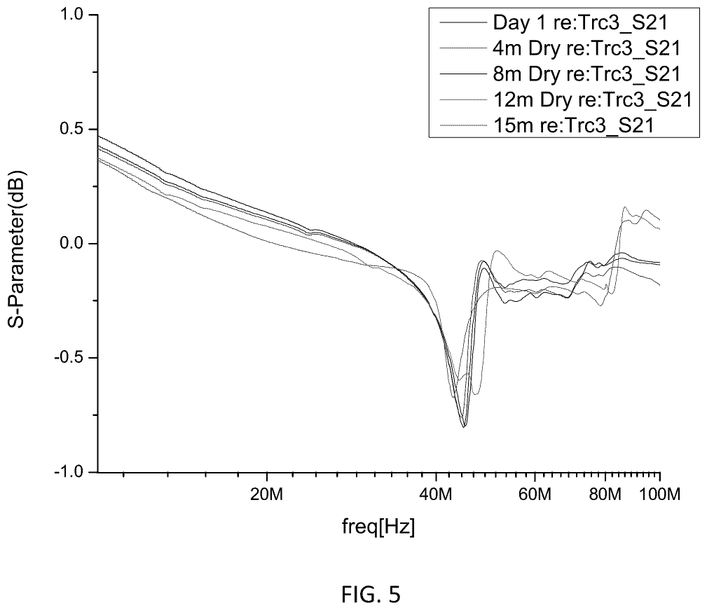

Frequency Range A: As shown in FIG. 5, after the 15-months corrosion time point, the S-parameter readings (S₂₁) of the cables in the wet and dry conditions showed a clear difference in the frequency range A (10 MHz to 100 MHz). This shows that corrosion of the cables affects the S-parameter readings of the cables in this frequency range. This frequency range was focused on in this example because it showed a clearer trend in values/signals than the 100 MHz to 600 MHz frequency range. The S-parameter signal can also be observed to become rougher as the corrosion time point increases.

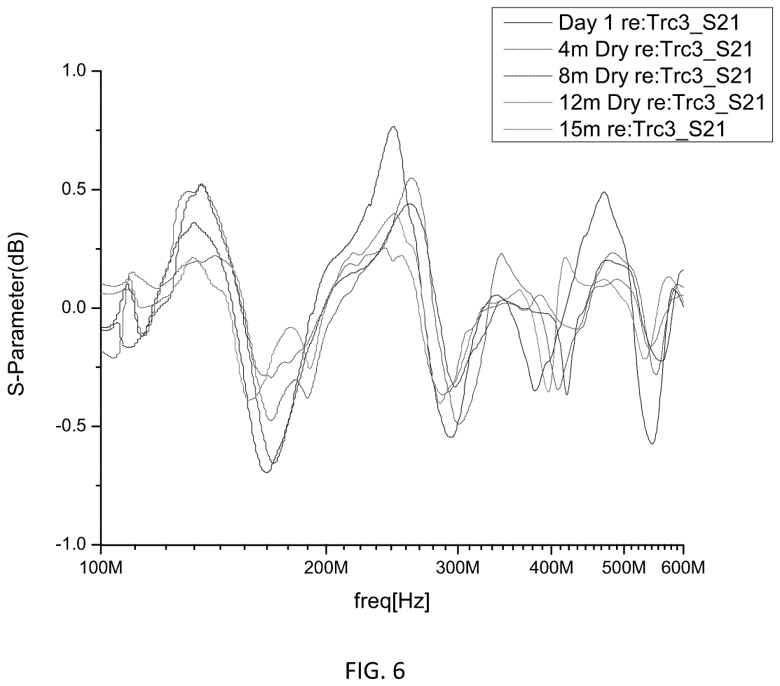

Frequency Range B: As shown in FIG. 6, after the 15-months corrosion time point, the S-parameter readings (S₂₁) of the cables in the wet and dry conditions showed a clear difference in the frequency range B (100 MHz to 600 MHz). This shows that corrosion of the cables affects the S-parameter readings of the cables in the 100 MHz-600 MHz frequency range. The S-parameter signal can also be observed to become rougher as the corrosion time point increases in this frequency range.

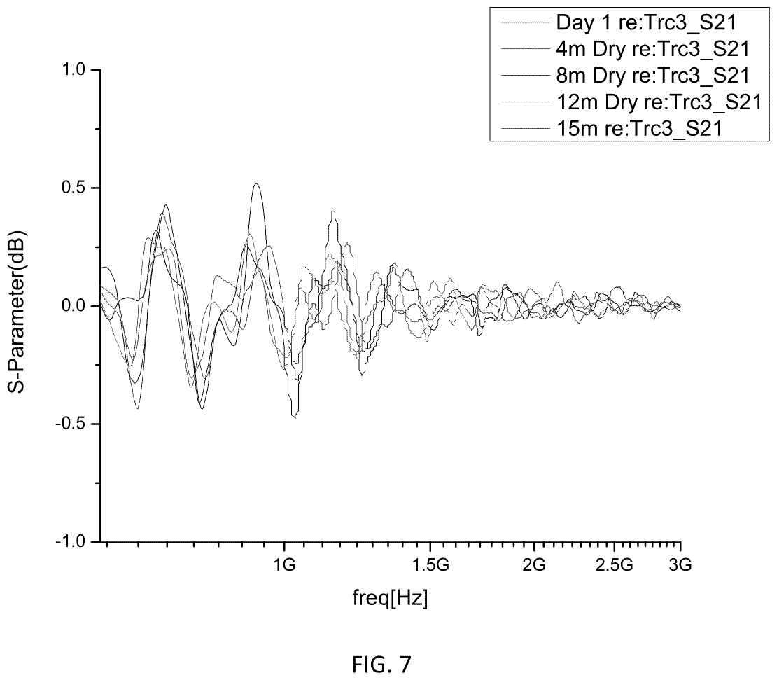

High Frequency Range: FIG. 7 shows the S-parameter result (S₂₁) of cable in dry condition after 15-months corrosion time point. As shown in FIG. 7, after the 15-months corrosion time point, the S-parameter readings (S₂₁) of the wet and dry solder joints showed a considerable difference in the high frequency range (600 MHz to 3 GHz). This shows that corrosion affects the S-parameter readings of the cables in the high frequency range. However, there are too many peaks in the S-parameter results. The S-parameter signal can also be observed to become rougher as the corrosion time point increases in this frequency range.

Representing Corrosion Growth in Cables

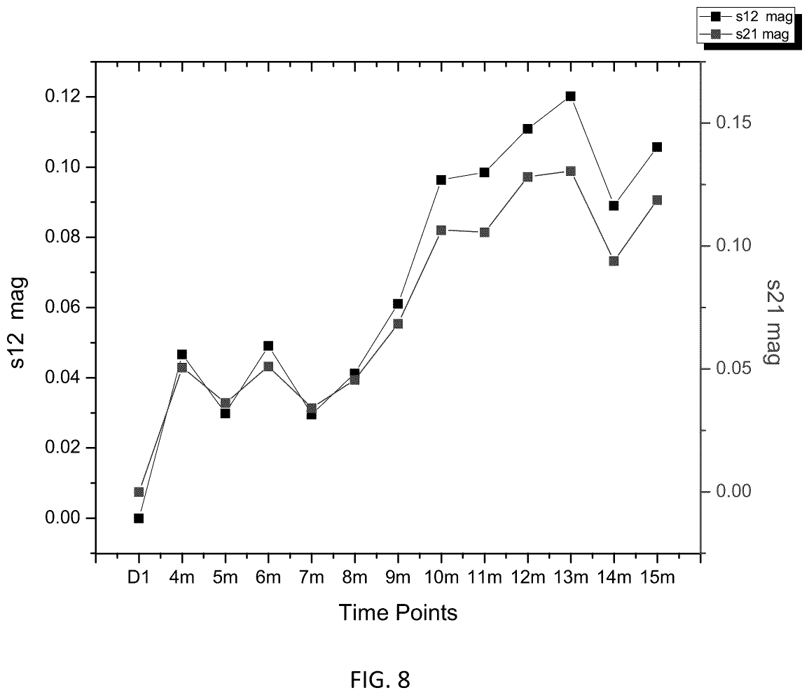

Computing Difference between S-signals of Cable in Wet conditions and Fresh Cable at Different Corrosion Time Point: The S-parameter readings of the wet cable obtained at different corrosion time points were studied to further investigate the effect of corrosion. The variation/difference in the S-parameter readings of the cables in the wet condition and fresh cables (at the beginning of the experiment) in the frequency range A (10 MHz to 100 MHz) was seen to increase as the corrosion time point increases. In order to validate this, the mean squared value of the difference between the S-parameter readings of the cable in the wet condition and that of the fresh cables was calculated up to the 15-month corrosion time points using the formula below.

$$\frac{{Σ}_{i = 1}^{n} {( {S}_{wi} - {S}_{D 0 i} )}^{2}}{n}$$

where S_{w} is S-parameter reading (real or magnitude) of the cable in wet condition, S_{D0} is S-parameter reading of the cable at the beginning of the experiment. FIG. 8 shows the mean squared value of the difference between the S-parameter readings (magnitude) of the cable in wet condition at several corrosion time points, and the fresh cable (day 0) calculated using equation 1 above. The single number was seen to increase as the corrosion time point increased meaning this number can be used to indicate the difference in the corrosion status of cables in wet condition. Overall, the trend shows an increase in variation of S-parameter readings as corrosion increases in the cable. However, there were some decreases in difference in some months which may be attributed to instrument measurement error. This shows that the S-parameters readings in this frequency range (10 MHz-100 MHz) can be used to indicate the difference in the corrosion status of cables.

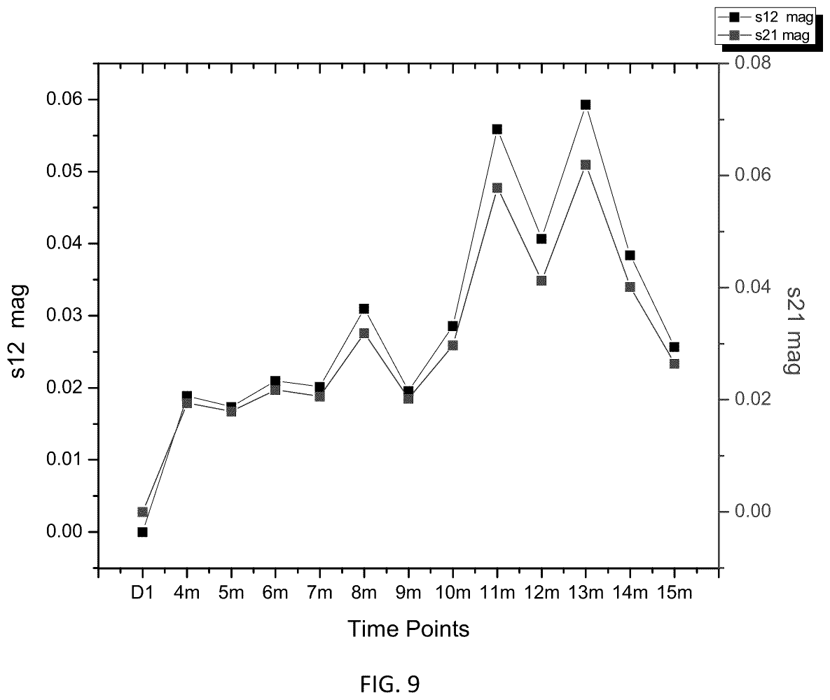

Computing Difference between S-signals of Cables in Wet and Dry condition at Different Corrosion Time Points: The variation/difference between the S-parameter readings of the cables in the wet and dry conditions in the frequency range A (10 MHz to 100 MHz) was seen to increase as the corrosion time point increases. In order to validate this, the mean squared value of the difference between the S-parameter readings of the cable in the wet and dry condition was also calculated up to the 15-month corrosion time points. using the formula below.

$$\frac{{Σ}_{i = 1}^{n} {( {S}_{wi} - {S}_{di} )}^{2}}{n}$$

where S_{w} is S-parameter reading (real or magnitude) of the cable in wet condition and S_{d} is S-parameter reading of the cable in dry condition. FIG. 9 below shows the computed numerical difference (mean squared value) of S-parameter readings between the wet and dry cables from the beginning of the experiment to 15-month corrosion time point in the frequency range B (10 MHz to 100 MHz). The single number was also seen to increase as the corrosion time point increased meaning this number can be used to indicate the difference in the corrosion status of cables in dry and wet condition. However, for some months the number reduced, which may be attributed to the difference in the corrosion growth rate between the cables in the dry and wet condition. This shows that the S-parameters readings in this frequency range (10 MHz-100 MHz) can be used to indicate the difference in the corrosion status of cables.

Quantifying the Roughness in S-Signals as Corrosion Time Point Increases. As discussed above, there is an evident increase in the roughness of the S-parameter signals obtained as the corrosion time point increases. We are currently focusing on devising ways to numerically characterize this roughness in the signals. By doing so, we aim to establish another method of representing the corrosion status in the cables.

Rusty Bolt Effect and Skin Effect: The change in S-parameter readings between the wet and dry cables due to corrosion can be attributed to a phenomenon called rusty bolt effect or passive intermodulation. Rusty bolt effect is a form of radio interference due to interactions of the radio waves/signals with dirty connections or corroded parts. It is properly known as passive intermodulation (PIM). PIM is a form of intermodulation distortion that occurs in components normally thought of as linear, such as cables, connectors, and antennas. Corroded materials on cables can act as one or more diodes generating non-linearity. Here oxidation of the conductors and solder joints causes the generation of non-linearity in the conductors. Passive intermodulation in the cables produces unwanted signals/interference in the S-parameter readings, and this can sometimes hide the wanted signal.

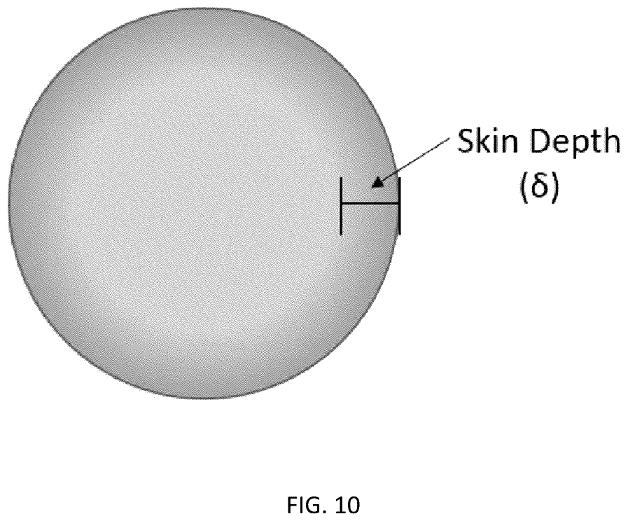

Skin effect is the tendency of an alternating electric current (AC) to become distributed within a cable such that the current density is largest near the surface of the cable and decreases exponentially with greater depths in the conductor. FIG. 10 shows a schematic of the skin depth of a cable.

TABLE 1
Skin Depth of Copper and Silver from 9 kHz to 100 MHz.

| | | |
|---|---|---|
| Frequency | Copper Skin depth (μm) | Silver Skin depth (μm) |

| | | | |
|---|---|---|---|
| 9 | kHz | 687.2 | 668.4 |
| 100 | MHz | 6.52 | 6.341 |
| 600 | MHz | 2.6616 | 2.5887 |
| 1 | GHz | 2.0617 | 2.005 |
| 3 | GHz | 1.1903 | 1.1577 |

Skin depth depends on the frequency of the alternating current; as frequency increases, current flow/signals move to the surface resulting in less skin depth. Skin effect reduces the effective cross-section of the cable. Table 1 shows the skin depth of the copper and silver cable at the considered frequencies. It can be seen that as the frequency increases, the skin depth and the effective cross-section of the cable reduces.

At the medium and large frequency ranges (100 MHz-600 MHz and 600 MHz-3 GHz), since the signal travels near the surface of the cable (small skin depth) and the corrosion also occurs on the surface of the cable, corroded spots on the cables act as one or more diodes. This produces unwanted signals/interference and can sometimes hide the wanted signal. Therefore, we can see the slight difference between the obtained S-parameter readings of the wet and dry conductor between 100 MHz-600 MHz and 600 MHz-3 GHz.

However, at low frequency range (9 KHz-100 MHz), the cross-sectional area for signal transmission is large (large skin depth) while corrosion also occurs on the surface of the cable. Due to the large cross-sectional area for signal transmission, the effect of the mixing of the unwanted signal with the desired signal is minimal. This makes the interference due to corrosion on surface negligible. Therefore, there is no difference between the obtained S-parameter readings between 9 KHz and 100 MHz.

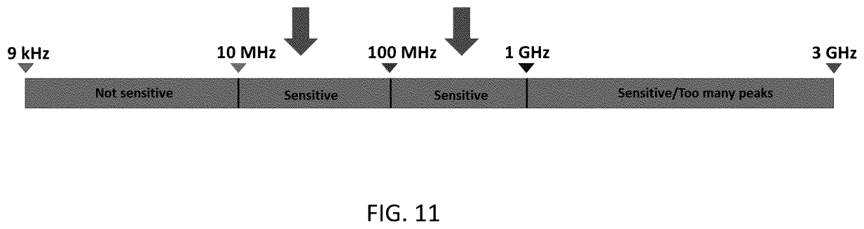

Overall, the frequency ranges (10 MHz-100 MHz and 100 MHz-1 GHz) can be used to monitor the corrosion as shown in FIG. 11. As the corrosion in the cable increases, it is believed to cause both the electric (E) and magnetic (H) fields to bend around it causing a reduction in amplitude of the S-parameter readings. Attenuation and reflection of the signal is observed to increase as corrosion depth or area increases in the cables.

Other S-parameter Signals and Frequency Ranges: As discussed above, the S₂₁ S-parameter signal (magnitude) and frequency range B (100 MHz-600 MHz) are focused. However, it should be noted that other S-parameter signals and frequency ranges can also be utilized to practice the invention.

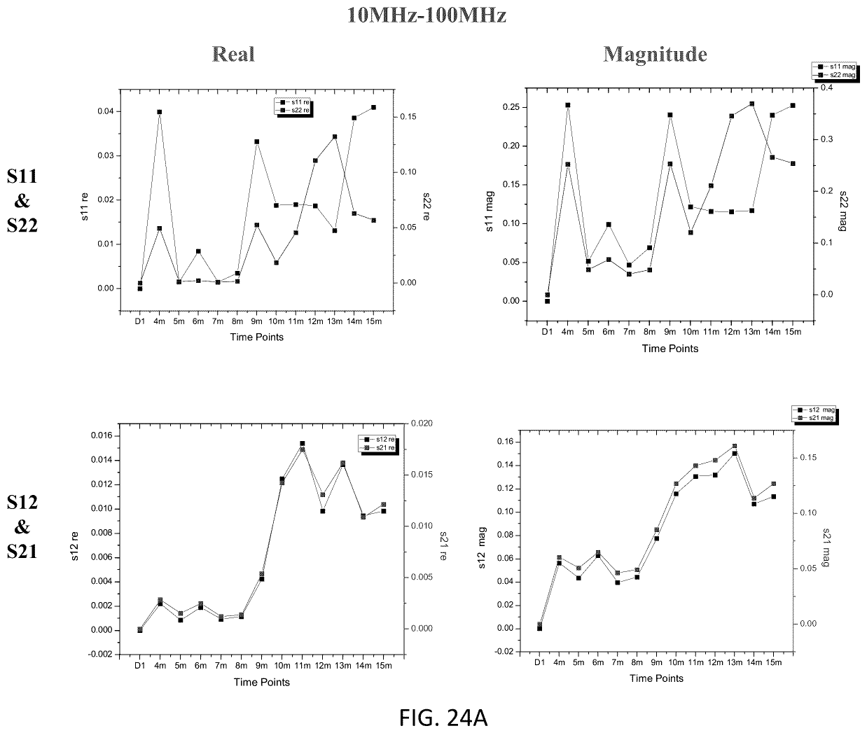

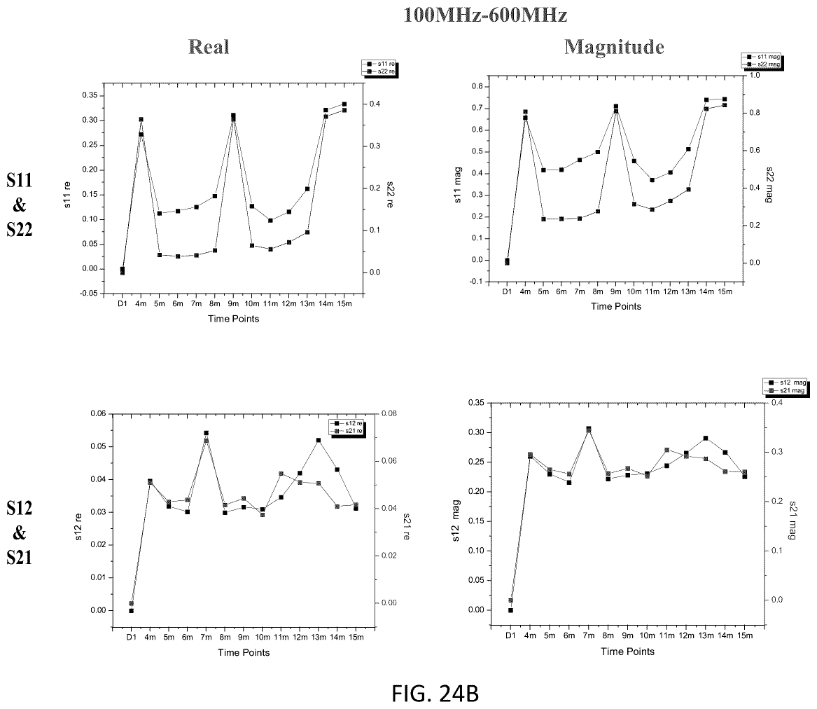

FIG. 24A shows computing difference between S-signals (S₁₁, S₁₂, S₂₁, S₂₂) of cable in dry conditions and fresh cable at different corrosion time points at a frequency range of 10 MHz-100 MHz.

FIG. 24B shows computing difference between S-signals (S₁₁, S₁₂, S₂₁, S₂₂) of cable in dry conditions and fresh cable at different corrosion time points at a frequency range of 100 MHz-600 MHz.

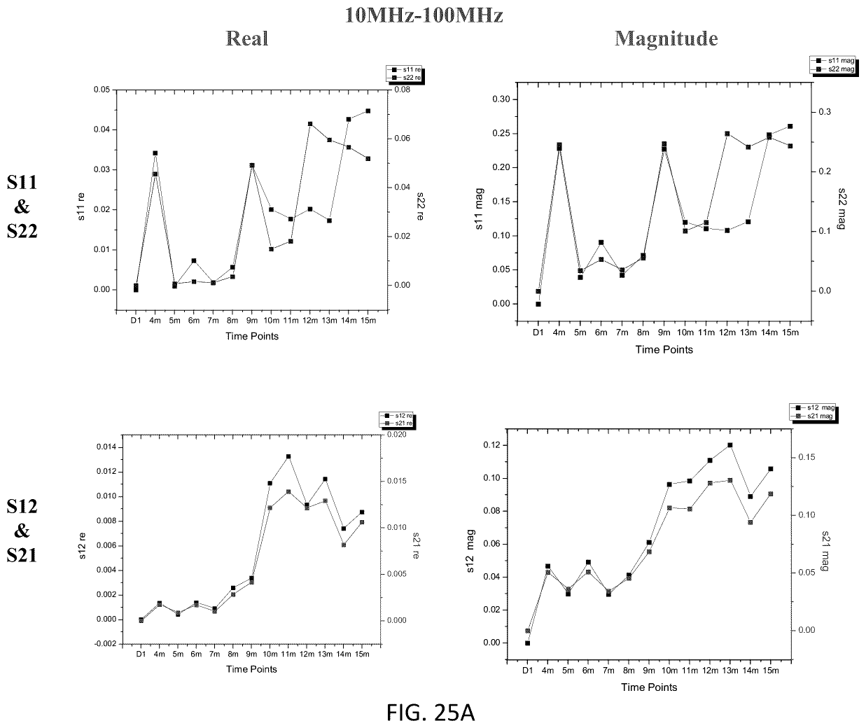

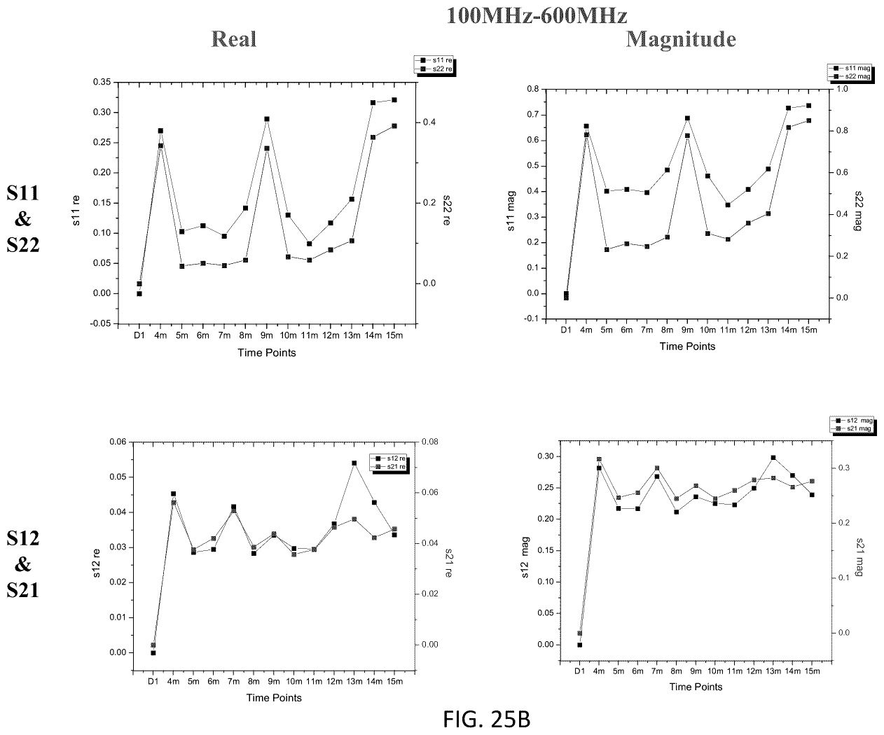

FIG. 25A shows computing difference between S-signals (S₁₁, S₁₂, S₂₁, S₂₂) of cable in wet conditions and fresh cable at different corrosion time points at a frequency range of 10 MHz-100 MHz.

FIG. 25B shows computing difference between S-signals (S₁₁, S₁₂, S₂₁, S₂₂) of cable in wet conditions and fresh cable at different corrosion time points at a frequency range of 100 MHz-600 MHz.

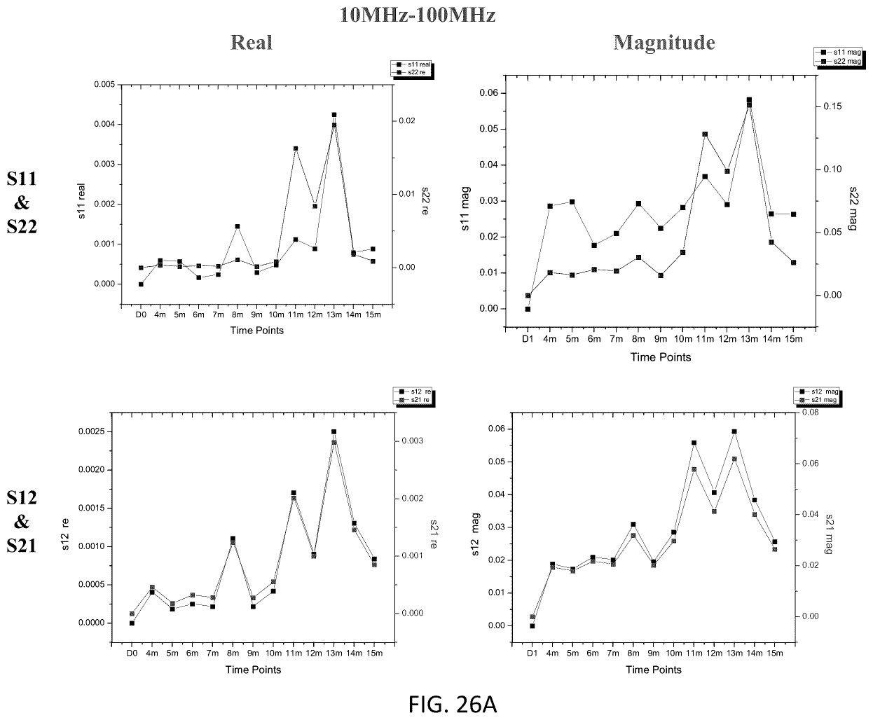

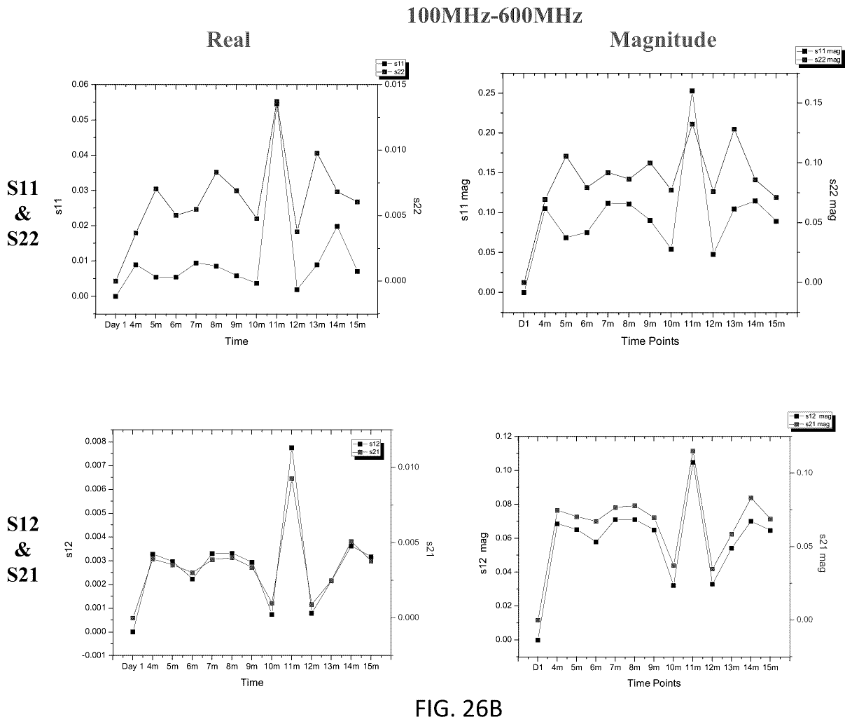

FIG. 26A shows computing difference between S-signals (S₁₁, S₁₂, S₂₁, S₂₂) of cables in wet and dry condition at different corrosion time points at a frequency range of 10 MHz-100 MHz.

FIG. 26B shows computing difference between S-signals (S₁₁, S₁₂, S₂₁, S₂₂) of cables in wet and dry condition at different corrosion time points at a frequency range of 100 MHz-600 MHz.

### Second Set

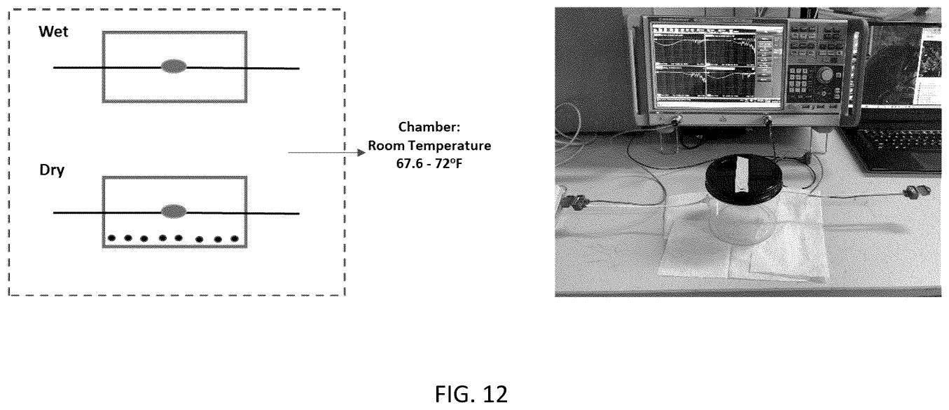

The second set also contains two 12-inches-long thick silver coated cables with soldered joints placed in a wet and dry condition at room temperature to verify the results obtained in the first set of experiment as shown in FIG. 12. The state of red plague corrosion in the three cables is being monitored as time progresses and the S-parameter reading would be obtained at various corrosion time points. This has reached the 5-month corrosion time point. Nonetheless, it is to be noted that new set of test cables were used with the network analyzer to obtain the results.

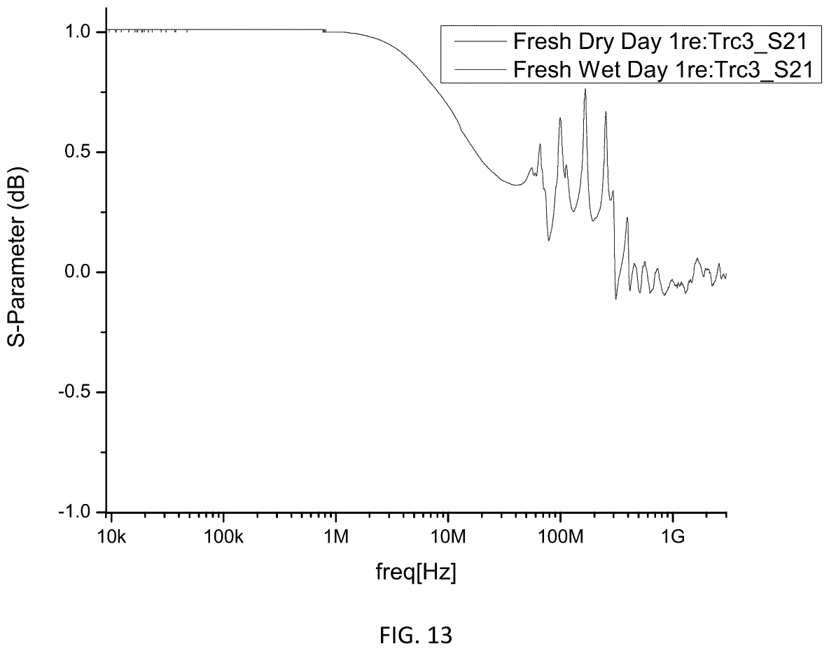

To start with, the S-parameter readings were also obtained for the cables with solder joints in wet and dry conditions at the beginning of the experiment (day 1). FIG. 13 shows the S-parameter reading (S₂₁) at the beginning of the experiment for the whole frequency spectrum (9 kHz to 3 GHz). From FIG. 13, it shows that the S-parameter readings for the cables in wet and dry conditions are the same in all frequency ranges at the start of the experiment.

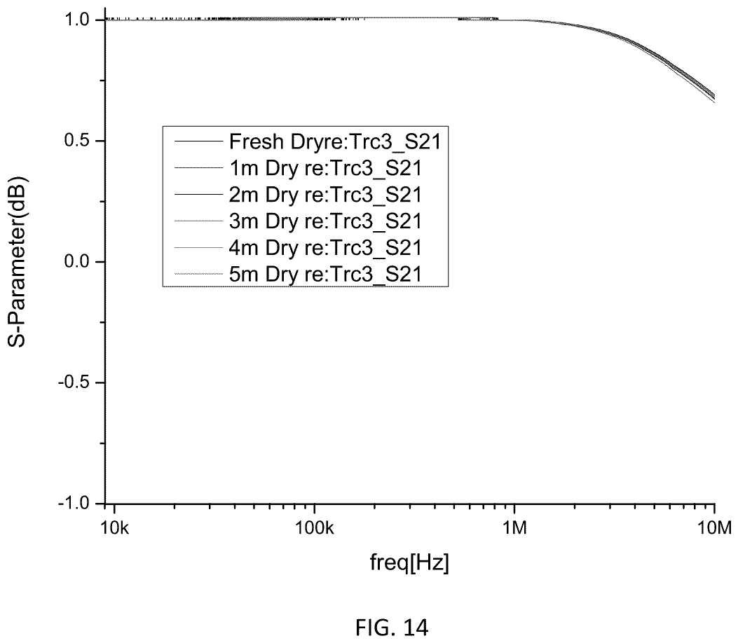

Low Frequency Range: As shown in FIG. 14, after the 5-months corrosion time point, the S-parameter readings (S₂₁) of the wet and dry solder joints showed no difference in the low frequency range (9 kHz to 10 MHz). This shows that corrosion does not affect the S-parameter readings of the cables in this range. Therefore, the rate of corrosion of the cables in wet and dry conditions has no influence on the S-parameter readings of the cables in the low frequency range.

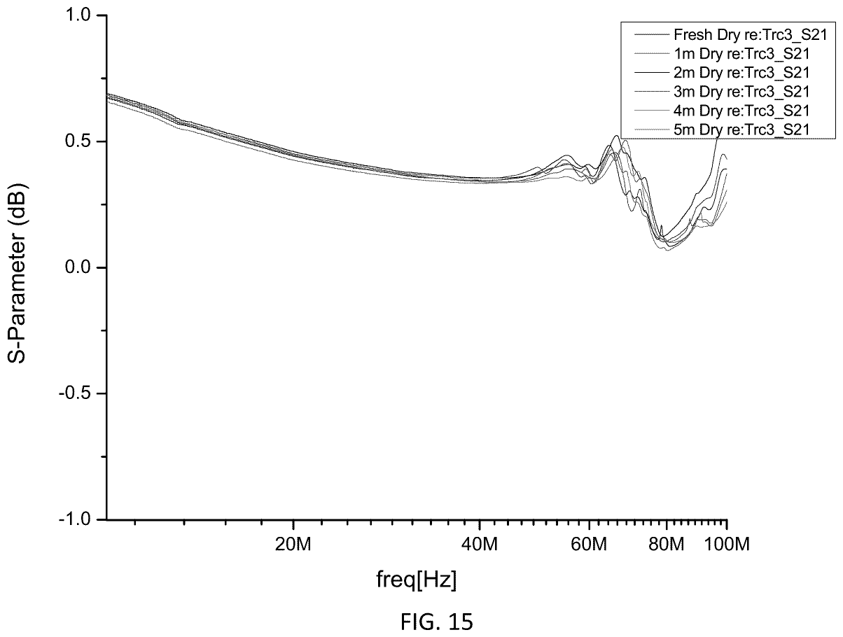

Frequency Range A: As shown in FIG. 15, after the 5-months corrosion time point, the S-parameter readings (S₂₁) of the cables in the wet and dry conditions showed a clear difference in the frequency range B (10 MHz to 100 MHz). This shows that corrosion on the cables affects the S-parameter readings of the cables in this frequency range. This frequency range was also focused on in this report because it showed a clearer trend in values/signals than the 100 MHz to 600 MHz frequency range.

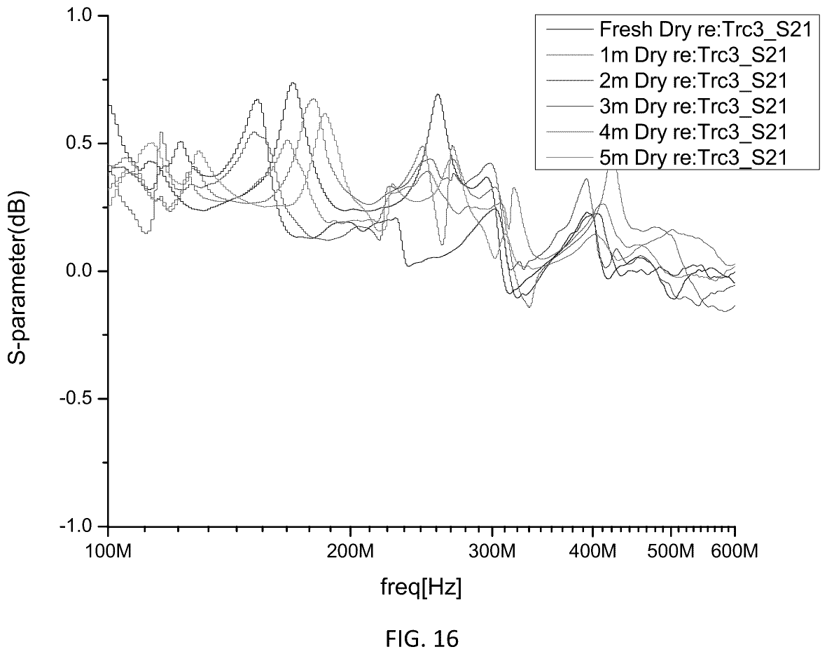

Frequency Range B: As shown in FIG. 16, after the 5-months corrosion time point, the S-parameter readings (S₂₁) of the cables in the wet and dry conditions showed a clear difference in the frequency range B (100 MHz to 600 MHz). This shows that corrosion of the cables affects the S-parameter readings of the cables in this frequency range. Therefore, this frequency range can also be used to monitor corrosion in cables.

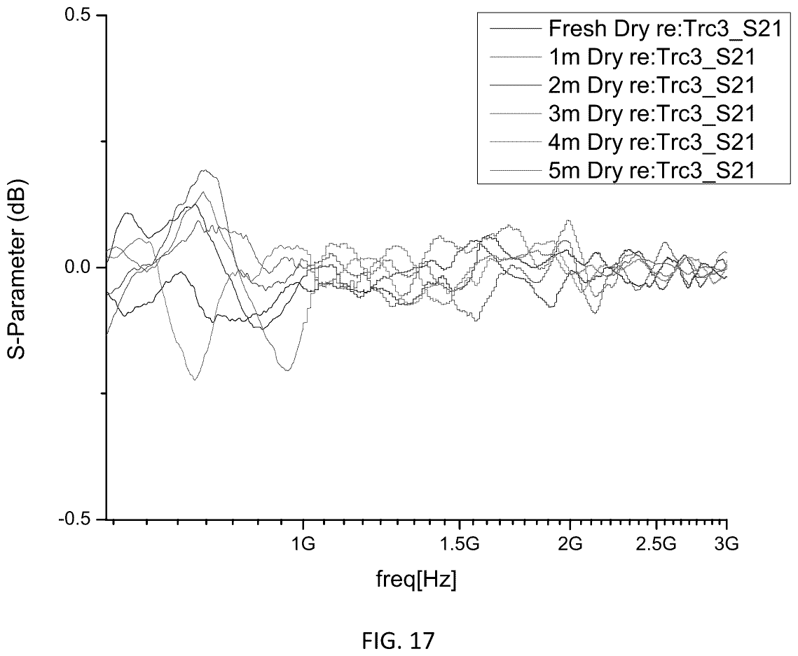

High Frequency Range: FIG. 17 shows the S-parameter result (S) of the wet and dry conductor joints after 5-months corrosion time point. As shown in FIG. 17, after the 5-months corrosion time point, the S-parameter readings (S₂₁) of the wet and dry solder joints showed a considerable difference in the high frequency range (600 MHz to 3 GHz). This shows that corrosion affects the S-parameter readings of the cables in the high frequency range. However, there are too many peaks in the S-parameter results.

Representing Corrosion Growth in the Cables

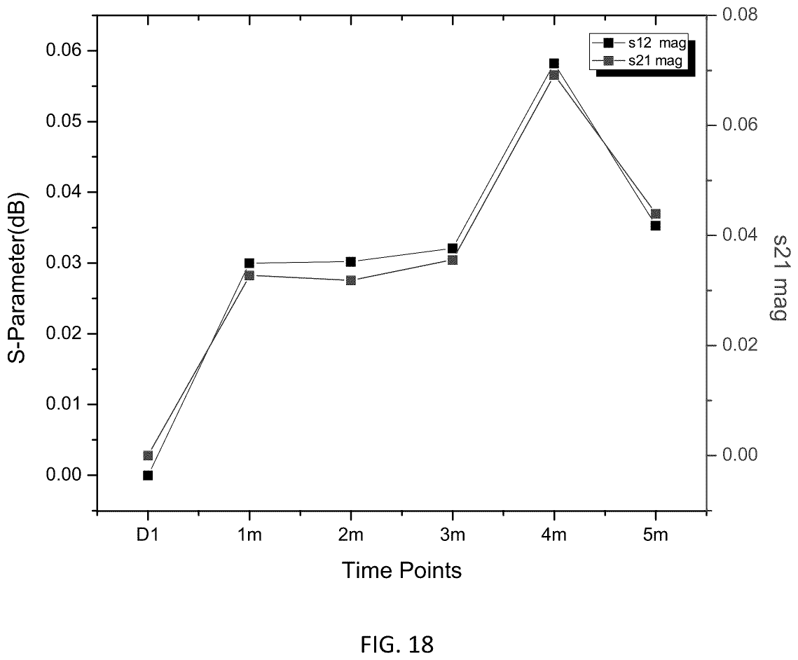

Computing Difference between S-signals of Cable in Wet conditions and Fresh Cable at Different Corrosion Time Points. The S-parameter readings of the wet cable obtained at different corrosion time points were also studied in this set to further investigate the effect of corrosion and confirm results in the first set. The variation/difference in the S-parameter readings of the cables in the wet condition and fresh cables (at the beginning of the experiment) in the frequency range A (10 MHz to 100 MHz) seen to increase as the corrosion time point increases. In order to validate this, the mean squared value of the difference between the S-parameter readings of the cable in the wet condition and that of the fresh cables was calculated up to 5-month corrosion time points using the formula below.

$$\frac{{Σ}_{i = 1}^{n} {( {S}_{wi} - {S}_{D 0 i} )}^{2}}{n}$$

Where S_{w} is S-parameter reading (real or magnitude) of the cable in wet condition, S_{D0} is S-parameter reading of the cable at the beginning of the experiment. FIG. 18 shows the mean squared value of the difference between the S-parameter readings (magnitude) of the cable in wet condition at several corrosion time points, and the fresh cable (day 1) calculated using equation 3 above. The single number was seen to also increase as the corrosion time point increased meaning this number can be used to indicate the difference in the corrosion status of cables in wet condition. Overall, the trend shows an increase in variation of S-parameter readings as corrosion increases in the cable. However, there was a decrease in difference in the 5^{th} month which may be attributed to instrument/measurement error. This shows that the S-parameters readings in this frequency range (10 MHz-100 MHz) can be used to indicate the difference in the corrosion status of cables. These results agree with the first set of experiment.

Computing Difference between S-signals of Cables in Wet and Dry condition at Different Corrosion Time Points. The variation/difference between the S-parameter readings of the cables in the wet and dry conditions in the frequency range A (10 MHz to 100 MHz) was seen to increase as the corrosion time point increases. In order to validate this, the mean squared value of the difference between the S-parameter readings of the cable in the wet and dry condition was calculated up to the 5-month corrosion time points. using the formula below.

$$\frac{{Σ}_{i = 1}^{n} {( {S}_{wi} - {S}_{di} )}^{2}}{n} \qquad ( a1 )$$

where S_{w} is S-parameter reading (real or magnitude) of the cable in wet condition and S_{d} is S-parameter reading of the cable in dry condition. FIG. 9 below shows the computed numerical difference (mean squared value) of S-parameter readings between the wet and dry cables from the beginning of the experiment to 15-month corrosion time point in the frequency range B (10 MHz to 100 MHz). The single number was also seen to increase as the corrosion time point increased meaning this number can be used to indicate the difference in the corrosion status of cables in dry and wet condition. However, for the fifth month the number reduced, which may be attributed to the difference in the corrosion growth rate between the cables in the dry and wet condition. This shows that the S-parameters readings in this frequency range (10 MHz-100 MHz) can be used to indicate the difference in the corrosion status of cables. These results also agree with the first set of experiments.

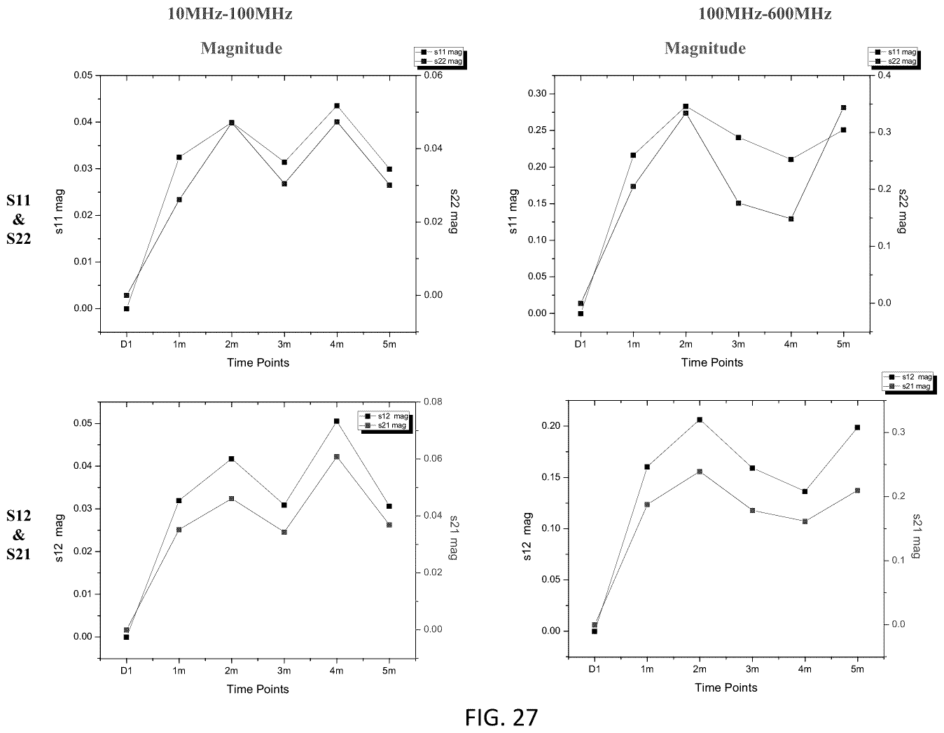

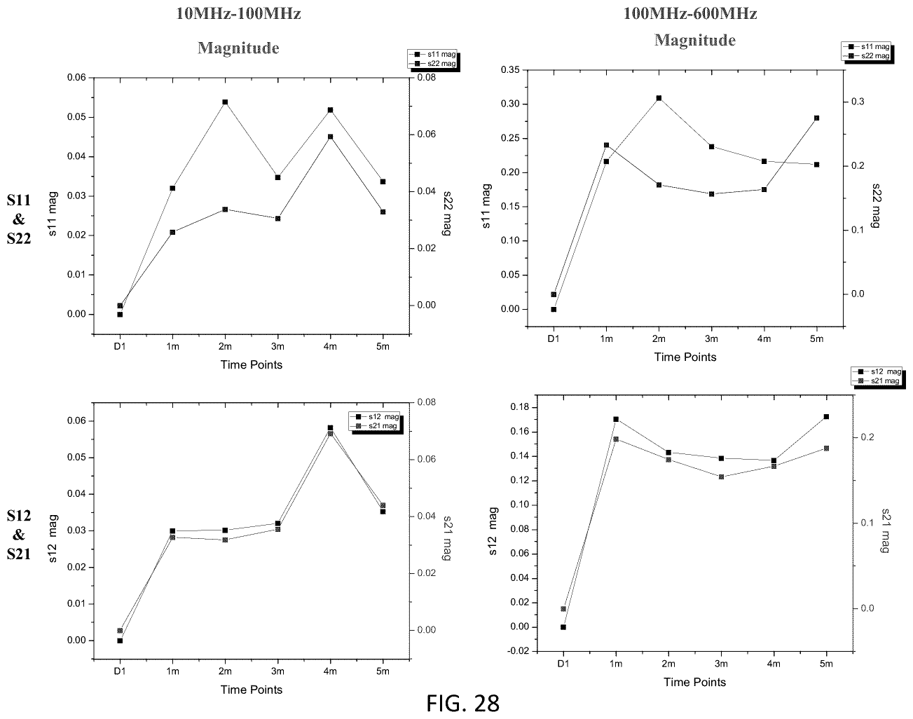

Other S-parameter Signals and Frequency Ranges: FIG. 27 shows computing difference between S-signals (S₁₁, S₁₂, S₂₁, S₂₂) of cable in dry conditions and fresh cable at different corrosion time points at a frequency range of 10 MHz-100 MHz and 100 MHz-600 MHz. FIG. 28 shows computing difference between S-signals (S₁₁, S₁₂, S₂₁, S₂₂) of cable in wet conditions and fresh cable at different corrosion time points at a frequency range of 10 MHz-100 MHz and 100 MHz-600 MHz.

### Third Set

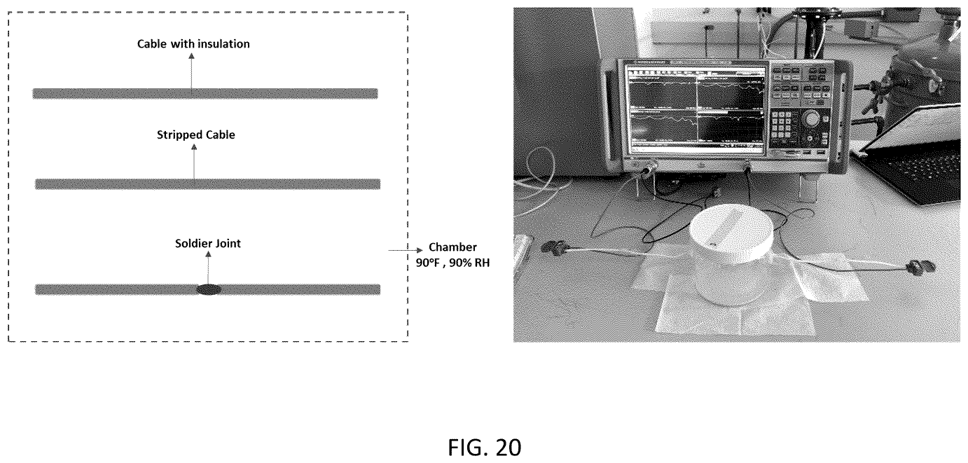

The third set of experiment contains a 12-inches-long silver-coated copper cable with insulation, a stripped 12-inches-long cable without insulation and 12-inches-long cable with solder joint, all maintained at 90° F. and 90% relative humidity to further verify the effect of corrosion on the S-parameter readings and confirm the results obtained in the first and second set of experiments. The schematic and setup are shown in FIG. 20.

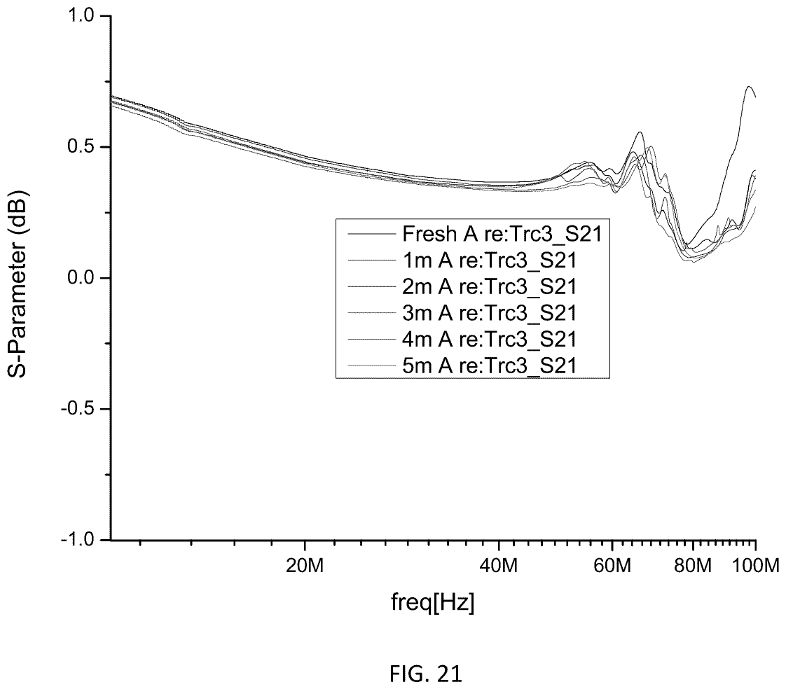

Frequency Range A: As shown in FIG. 21, after the 5-months corrosion time point, the S-parameter readings (S₂₁) of the 12-inches-long cable with solder joint showed a clear difference in the frequency range B (10 MHz to 100 MHz). This shows that corrosion of the cables also affects the S-parameter readings of the cables in this frequency range. This frequency range was also focused on in this section because it showed a clearer trend in values/signals than the 100 MHz to 600 MHz frequency range.

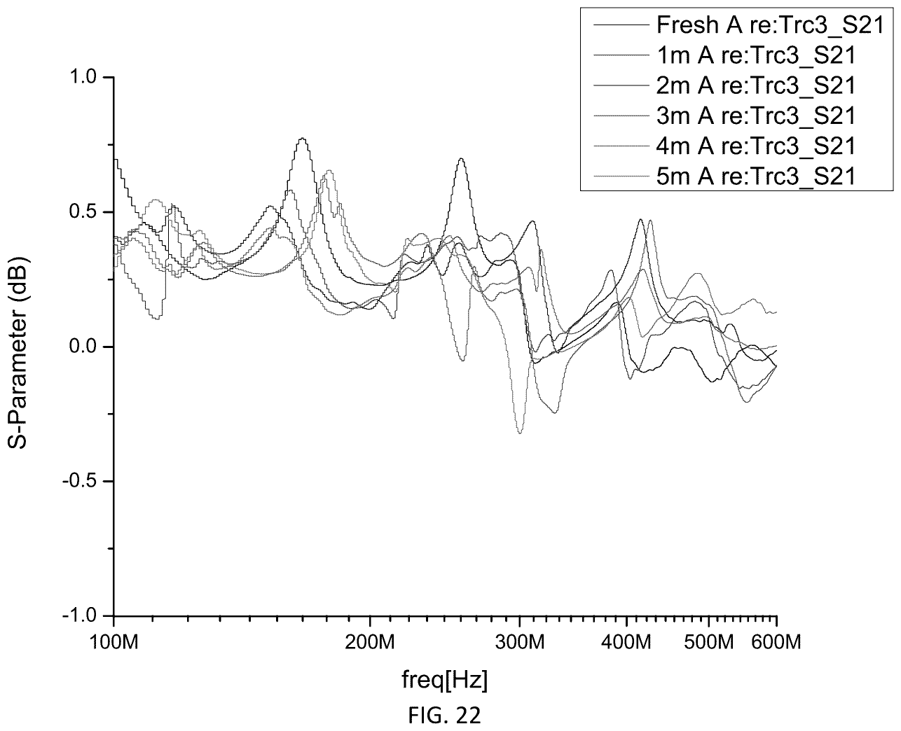

Frequency Range B: As shown in FIG. 22, after the 5-months corrosion time point, the S-parameter readings (S₂₁) of the 12-inches-long cable with solder joint show a clear difference in the frequency range B (100 MHz to 600 MHz). This shows that corrosion of the cables affects the S-parameter readings of the cable in the 100 MHz-600 MHz frequency range.

Representing Corrosion Growth in the Cables

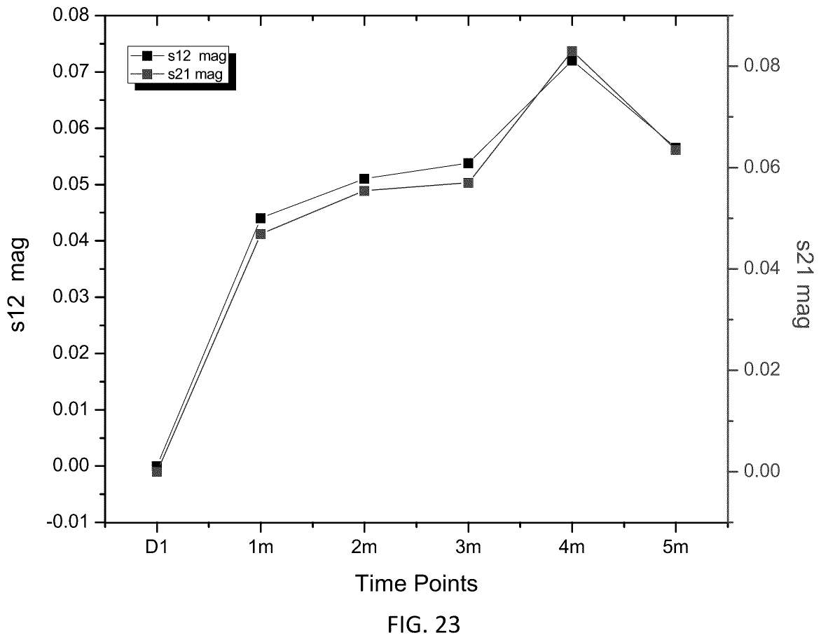

Computing Difference between S-signals of Cable in High Humidity Condition and Fresh Cable at Different Corrosion Time Points. The S-parameter readings of the cables obtained at different corrosion time points were studied to further investigate the effect of corrosion. The variation/difference in the S-parameter readings of the cables in high humidity condition and fresh cables (at the beginning of the experiment) in the frequency range A (10 MHz to 100 MHz) was seen to increase as the corrosion time point increases. In order to validate this, the mean squared value of the difference between the S-parameter readings of the two 6-inch cables joined by a solder joint and that of the fresh cable was calculated up to 5-month corrosion time points using the formula below.

$$\frac{{Σ}_{i = 1}^{n} {( {S}_{wi} - {S}_{D 0 i} )}^{2}}{n}$$

where S_{w} is S-parameter reading (real or magnitude) of the cable in wet condition, S_{D0} is S-parameter reading of the cable at the beginning of the experiment. FIG. 23 shows the mean squared value of the difference between the S-parameter readings (magnitude) of the cable in wet condition at several corrosion time points, and the fresh cable (day 1) calculated using equation 3 above. The single number was seen to increase as the corrosion time point increased meaning this number can be used to indicate the difference in the corrosion status of cables in wet condition. Overall, the trend shows an increase in variation of S-parameter readings as corrosion increases in the cable. However, there was a decrease in difference in the 5^{th} month which may be attributed to instrument measurement error. This shows that the S-parameters readings in this frequency range of 10 MHz-100 MHz can be used to indicate the difference in the corrosion status of cables.

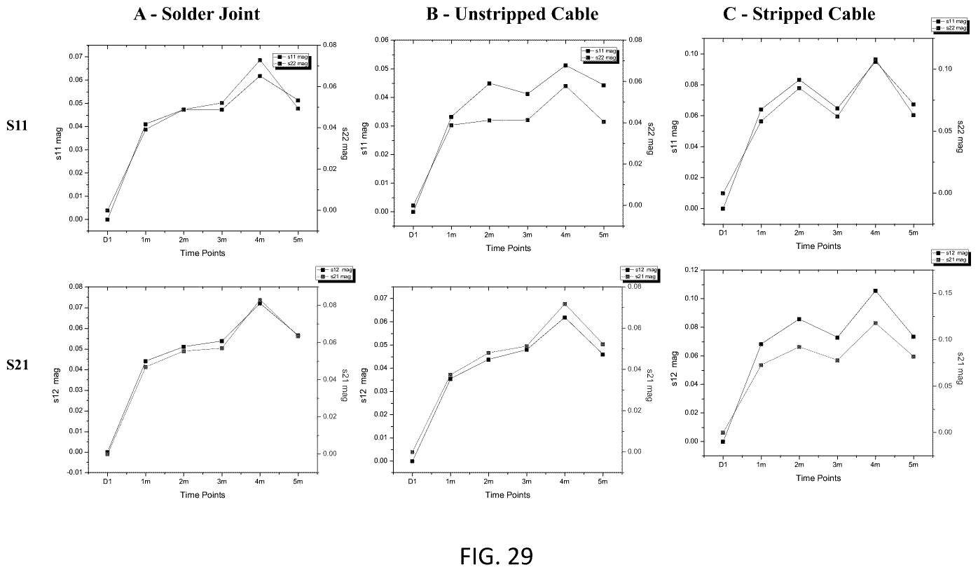

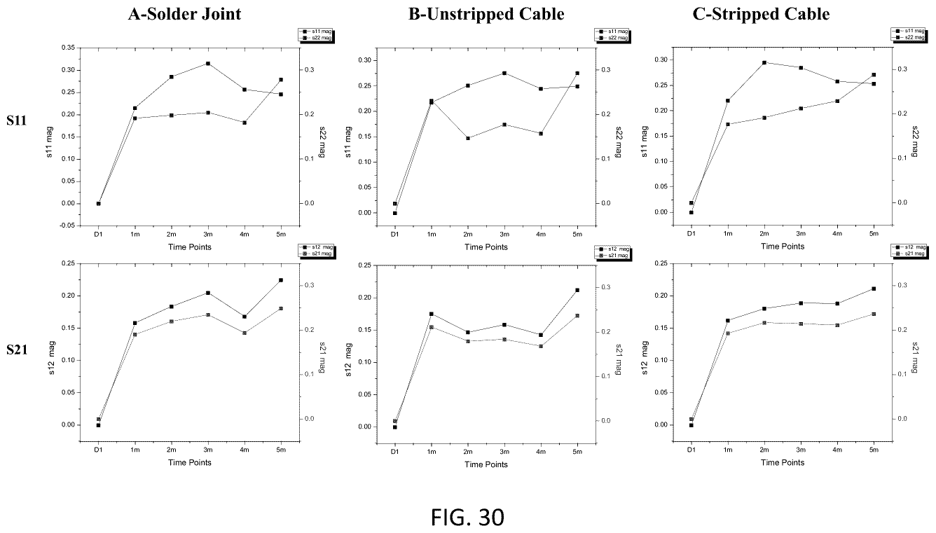

Other S-parameter Signals and Frequency Ranges: FIG. 29 shows computing difference between S-signals (S₁₁, S₁₂, S₂₁, S₂₂) of cables and fresh cable at different corrosion time points at a frequency range of 10 MHz-100 MHz. FIG. 30 shows computing difference between S-signals (S₁₁, S₁₂, S₂₁, S₂₂) of cables and fresh cable at different corrosion time points at a frequency range of 100 MHz-600 MHz.

### CONCLUSION

All three sets of experiments show that the S-parameter signal or S-signal (Sij) can be used to monitor red plague corrosion in the silver-plated copper cables and its sensitivity varies with frequency. S-signal at low frequencies (<10 MHz) is less sensitive to the corrosion. S-signal at high frequencies (>1 GHz) is too sensitive to many detailed aspects of the corrosion in cable so it may not be used to monitor the corrosion of a cable. However, S-signal at medium frequency ranges (10 MHz-1 GHZ) is sensitive to corrosion and can be further divided into two subranges: frequency range A of 10 MHz-100 MHZ and frequency range B of 100 MHz to 1 GHz.

S-signal in frequency range B of 100 MHz to 1 GHz is highly sensitive to the initial stages (first 4-5 months) of cable corrosion, and a simple number based on the S-signal in this frequency range can be used to monitor the corrosion severity. However, beyond 7 months corrosion time point, the S-signal in this frequency range exhibits an unclear trend due to the increase in cable corrosion and skin effect.

S-signal in frequency range A of 10 MHz-100 MHZ is more suitable for monitoring corrosion in a cable. A significant increase in variation between the S-parameter signal of the original cable (Day 1) and cables at different corrosion time points was observed in this frequency range. Moreover, the difference in S-signal between cables under dry and the other under wet conditions increased with time. Importantly, the S-signal in frequency range A showed a clearer trend in variations than that in frequency range B. Therefore, frequency range A is more suitable for monitoring the corrosion in cables.

The foregoing description of the exemplary embodiments of the present invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A method for nondestructively detecting corrosion of an object, comprising:
applying an electronic signal to a device under test (DUT) including said object;
measuring signal-transmission characteristics of said object; and
determining the corrosion of the object based on the measured signal-transmission characteristics of said object.

2. The method of claim 1, wherein said object includes a metallic cable or wire.

3. The method of claim 1, wherein the electronic signal varies in frequency in a range of 9 kHz-3 GHz.

4. The method of claim 3, wherein the signal-transmission characteristics comprises one or more of S-parameter signals at different frequencies, wherein the S-parameter signals include an input impedance, S₁₁, an output match/impedance, S₁₂, a forward gain/loss, S₂₁, and a reverse gain/loss, S₂₂, of the object.

5. The method of claim 4, wherein a magnitude of interference in the S-parameter signals is proportional to an amount, area, and depth of corrosion spots on said object.

6. The method of claim 4, wherein the S-parameter signals at a frequency range of 10 MHz-1 GHZ are sensitive to the corrosion.

7. The method of claim 6, wherein the frequency range is preferably from 10 MHz to 100 MHz.

8. The method of claim 1, wherein said determining the corrosion of said object comprises:
comparing the measured signal-transmission characteristics of said object with that of a known object in an uncorroded state to determine difference of the signal-transmission characteristics between said object and the known object.

9. The method of claim 8, wherein the known object is corresponding to said object in an uncorroded state.

10. The method of claim 8, wherein the signal-transmission characteristics of the known object is measured in-situ, or pre-measured.

11. The method of claim 4, wherein said determining the corrosion of said object comprises:
characterizing a roughness in the S-parameter signals; and
determining the corrosion of said object based on the roughness in the S-parameter signals.

12. The method of claim 11, wherein the roughness in the S-parameter signals increases as the corrosion time point increases.

13. A device for nondestructively detecting corrosion of an object, comprising:
a signal source for generating an electronic signal operably applied to a device under test (DUT) including said object;
a detector configured to measure signal-transmission characteristics of said object; and
a processor configured to determine the corrosion of the object based on the measured signal-transmission characteristics of said object.

14. The device of claim 13, wherein said object includes a metallic cable or wire.

15. The device of claim 13, wherein the electronic signal varies in frequency in a range of 9 kHz-3 GHz.

16. The device of claim 15, wherein the signal-transmission characteristics comprises one or more of S-parameter signals at different frequencies, wherein the S-parameter signals include an input impedance, S₁₁, an output match/impedance, S₁₂, a forward gain/loss, S₂₁, and a reverse gain/loss, S₂₂, of the object.

17. The device of claim 16, wherein a magnitude of interference in the S-parameter signals is proportional to an amount, area, and depth of corrosion spots on the object.

18. The device of claim 16, wherein the S-parameter signals at a frequency range of 10 MHz-1 GHZ are sensitive to the corrosion.

19. The device of claim 18, wherein the frequency range is preferably from 10 MHz to 100 MHz.

20. The device of claim 13, wherein the processor is configured to:
compare the measured signal-transmission characteristics of said object with that of a known object to determine difference of the signal-transmission characteristics between said object and the known object so as to determine the corrosion of said object.

21. The device of claim 20, wherein the known object is corresponding to said object in an uncorroded state.

22. The device of claim 21, wherein the signal-transmission characteristics of the known object is measured in-situ, or pre-measured.

23. The device of claim 16, wherein the processor is configured to:
characterize a roughness in the S-parameter signals; and
determine the corrosion of said object based on the roughness in the S-parameter signals.

24. The device of claim 23, wherein the roughness in the S-parameter signals increases as the corrosion time point increases.

25. The device of claim 13, wherein the signal source comprises a signal generator.

26. The device of claim 13, wherein the detector comprises one or more receivers coupled to input and output ports of the DUT.

27. The device of claim 13, being a network analyzer.
